(19) United States
(12) Patent Application Publication
(10) Pub. No.: US 2025/0116030 A1
(43) Pub. Date: Apr. 10, 2025

(54) Two-Dimensional Halide Perovskite Nanowires

(71) Applicant: Purdue Research Foundation, West Lafayette, IN (US)

(72) Inventors: Letian DOU, West Lafayette, IN (US); Wenhao SHAO, West Lafayette, IN (US)

(21) Appl. No.: 18/910,950

(22) Filed: Oct. 9, 2024

Related U.S. Application Data
(60) Provisional application No. 63/589,121, filed on Oct. 10, 2023.

(51) Int. Cl. C30B 29/12; C30B 11/00; C30B 29/62; G02B 6/10; H01S 5/20

(52) U.S. Cl. CPC C30B 29/12; C30B 11/003; C30B 29/62; G02B 6/107; H01S 5/2031

(57) ABSTRACT

Elongated single crystal layered halide perovskite nanowires with formula I (A)₂PbX₄, where A is an organic ammonium salt containing a carboxylated phenyl group and X is bromide or iodide; and processes for their manufacture and the use of single crystal layered halide perovskite nanowires as waveguides and micro-laser components are described.

### CROSS-REFERENCE TO RELATED APPLICATIONS

This application claims priority under 35 U.S.C. § 119 (e) to U.S. Provisional Application No. 63/589,121, filed Oct. 10, 2023, the entirety of the disclosure of which is incorporated herein by reference.

### GOVERNMENT FUNDING

This invention was made with government support under 2143568-DMR and 2110706-DMR awarded by the National Science Foundation and under DE-SC0022082 and DE-EE0009519 awarded by the Department of Energy. The government has certain rights in the invention.

### TECHNICAL FIELD

This disclosure relates generally to the field of semi-conductor engineering and, more particularly, to growing linear perovskite nanowires for use in photonic circuits and electronics.

### BACKGROUND

Semiconductor nanowires with precisely controlled morphology have captured widespread attention due to their exceptional and versatile properties. These nanostructures with high aspect ratios and subsequent confinement effects lay the foundation for innovative device architectures, optoelectronics. Meanwhile, mechanically flexible and optically anisotropic nanowires further open unique possibilities for customizing light-matter interactions, ultimately contributing to modern photonic integrated circuits and flexible electronics.

Morphological control was traditionally achieved in III-V semiconductor nanowires through the vapor-liquid-solid seeded growth that allows editable size, dimension, and epitaxial structures. However, despite their exceptional electronic properties, inorganic semiconductors are limited with high fabrication cost, elevated processing temperature, and lack of chemical tunability. Alternatively, organic semiconductor nanowires offer cost-effective solution processability, where one-dimensional self-assembly was achieved via anisotropic molecular packing motifs introduced with various supramolecular synthons and intermolecular interactions. Yet, organic derivatives are inherently limited by inferior charge carrier mobility and are subject to aggregation-induced luminescence quenching and high optical loss.

Organic-inorganic hybrid semiconductors, on the other hand, offer the option to synergize chemical tunability and solution processability with optical and electronic properties. These characteristics culminate in the advancement of metal halide perovskites with excellent carrier lifetime, diffusion length, high optical absorption coefficient, and tunable emission across the visible spectrum. Since the development of solution-phase nanowire growth using three-dimensional (3D) halide perovskites, substantial efforts have been dedicated to harnessing organic-inorganic hybrid semiconductors for next-generation nanowire photonics and electronics.

Significant tunability was achieved with the discovery of two-dimensional (2D) halide perovskites. The relaxed goldsmith factor enables the integration of bulky organic spacers to shield inorganic counterparts against ion migration, water, and oxygen, which are the detrimental factors affecting the chemical stability of 3D halide perovskites. Recent studies also aimed to incorporate sophisticated organic cations with engineered band gap and intermolecular π-interactions. Nevertheless, it remains a challenge to achieve precise morphological control in 2D halide perovskites, which, as its name would suggest, typically self-assemble into thin sheets with poor control over in-plane growth directions. Only limited attempts towards 1D growth such as exerting lithography-assisted templated growth or vapor-phase growth of (C₄H₉NH₃)₂PbI₄ have been reported, which suffers from low aspect ratio, high processing complexity, and limited design flexibility.

These limitations underscore the strong demand for tailor-designed organic spacers to control the morphology of 2D halide perovskite into nanowires for photonics applications. These organic components need to extend beyond single-molecule level and accelerate intermolecular communications as inspired from organic semiconductor nanowires.

### SUMMARY

Low-dimensional semiconducting materials with precisely controlled nanoscale morphology form the foundation for numerous technological breakthroughs. However, achieving one-dimensional (1D) nanostructures using inherently two-dimensional (2D) materials remains a rare and demanding endeavor. This limitation is addressed herein using hybrid 2D halide perovskites, which inherit the unique tunability of organics. A new “molecular clamp” approach is proposed that breaks the 4-fold symmetry, restricts crystal growth at selected crystal facets, and regulates 1D nanowire growth via tailored secondary bonding interactions. This approach is widely applicable to synthesize a range of high-quality 2D perovskite nanowires with large aspect ratios and tunable organic/inorganic chemical compositions. These nanowires form exceptionally well-defined and flexible cavities that exhibit versatile unusual optical properties including heterogeneous emission polarization, low-loss waveguiding (below 3 dB/mm), and efficient low-threshold light-amplification (below 20 μJ/cm²).

### BRIEF DESCRIPTION OF THE DRAWINGS

FIG. 1A comparison among the morphology and crystal structure of 2D [PbBr4]₂-perovskites based on various organic cations: (Panel A) PEA, phenylethylammonium, (B) mCA1, (3-carboxyphenyl)methylammonium, (Panel C) TPA3, 2-(2,5-dicarboxyphenoxy) ethethylammonium, and (Panel D) BrCA3, 2-(2-bromo-5-carboxyphenoxy)ethylammonium. (Panel E and F) further examined the 1D CA dimer chains observed in crystal structures of TPA3 and BrCA3-based 2D perovskites, respectively, and the out-of-plane examination of octahedral tilting. Cell axes shown in (Panels E and F) only represents the approximate length and angle.

FIG. 2 Optical and morphological properties of slow and fast-assembled crystals of (TPA3)₂PbBr₄. (Panels A-C) (TPA3)₂PbBr₄ obtained from slow-cooling over 72-96 hours. (Panel A) Bright field image; (Panel B) PL image; (Panel C) steady-state PL spectra. (Panels D-G) (TPA3)₂PbBr₄ obtained from fast floating growth. (Panel D) Bright field image; (Panel E) SEM image of the entire wire, (Panel F) bottom end facet, and (Panel G) top end facet. Data obtained at room temperature.

FIG. 3 Optical and morphological properties of slow and fast-assembled crystals of (TPA3)₂PbI₄. (Panels A-B) Bright-field images of (TPA3)₂PbI₄ obtained from fast floating growth showing branching and hyperbranching behaviors. (Panels C-E) (TPA3)₂PbI₄ obtained from slow-cooling over 72-96 hours. (Panel C) Bright field image; (Panel D) PL image; (Panel E) steady-state PL spectra showing a broad excitonic peak with a FWHM of 36.9 nm or 0.158 eV. Data obtained at room temperature.

FIG. 4 Growth rates of the long and short axis of a series of (BrCA3)₂PbBr₄ nanowires monitored with bright field optical microscopy during their in-situ growth at the air-liquid interface. Floating growth was proceeded at 70° C. Scale bars: 20 μm. The length-time relationship clearly deviated from linearity. In-situ monitoring did not initiate from the nucleation stage. However, the growth rate was still much faster at the beginning stage when monitoring started. As growth proceeded, supply of precursors gradually decreased which was accompanied by a reduced growth rate. Growth at the later stage would become diffusion limited, giving a near-linear length-time relationship. To present the growth rate, the data points were selectively fit at the later stage of monitoring where growth could be diffusion limited and length-time relationship appeared linear. According to the growth rate extracted here, the long axis exhibited much faster growth compared with the short axis by a factor of (Panel A) 41, (Panel B) 37, (Panel C) 42, and Panel (D) 46.

FIG. 5 Face-indexing of 1D (BrCA3)2PbBr4 nanowires in comparison with 2D (PEA)2PbBr4 sheets. (Panel A) A bulk hexagonal cylindrical crystal of (BrCA3)2PbBr4 (triclinic) face-indexed with SC-XRD indicating the side faces as (1̅10), (1̅13), (11̅3), and their parallel counterparts. (Panel B) Cross-section view of the crystal structure of (BrCA3)₂PbBr₄ at the (221 ) end facet along the crystallographic direction. The three pairs of faces indexed from the hexagonal cylindrical crystal were marked. Red shades represent the dangling carboxylic acid groups at each surface. All six faces exhibited pronounced coverage by CA moieties, clearly showing the surface protection attributes of dangling CA units. (Panel C) In comparison, the (100) side plane of (PEA)₂PbBr₄ lacks any surface protection groups. Thus, the growth drives the formation of 2D sheets of (PEA)₂PbBr₄. (Panel D) Animated growth of (PEA)₂PbBr₄ 2D sheets v.s. (Panel E) (BrCA3)₂PbBra₄ 1D nanowires.

FIG. 6 Face-indexing of (TPA3)2PbBr4. (Panel A) A bulk crystal of (TPA3)2PbBr4 (monoclinic) face-indexed with SC-XRD exhibiting the “stacking plane” (100) as the major side face. (Panel B) Cross-section view of the crystal structure at (100) plane reveals parallel alignment of H-bonding network with the short axis. In other words, growth of nanowire (long axis) is clearly perpendicular to the alignment of H-bonds. Red shades marks the surface dangling COOH units, which only exist at the side faces. These results indicate that the surface dangling CA units, again, protects selected crystal faces and drives the 1D growth of nanowires.

FIG. 7 Growth mechanism of 2D perovskite nanowires illustrated with (BrCA3)₂PbBr₄, morphological, and optical properties. (Panel A) stacking plane out-of-plane view. (Panel B) A bulk hexagonal cylindrical crystal face-indexed with SC-XRD indicating the side faces as (1̅10), (1̅13), (11̅3), and their parallel counterparts. (Panel C) TEM images of a nanowire and its SAED pattern (inset, viewed along zone axis [114]) showing the growth along the [110] direction. (Panel D) Cross-section view at the (221̅) end facet along the [110] direction. The three pairs of faces indexed from the hexagonal cylindrical crystal were marked. Red shades represent the dangling COOH at each surface. All six faces exhibited pronounced COOH coverage, clearly showing its surface protection attribute. (Panels E-G) End-facet morphology of miniaturized nanowires examined with SEM. (Panel H) SEM image of a 180°-twisted nanowire. (Panel I) PL image and (Panel J) spectrum of the twisted nanowire presented in FIG. 1, Panel D, showing white emission.

FIG. 8 Distinct surface dangling COOH on (1̅10) vs (221̅) surface and surface energy calculations. (Panel A) 2D side view of a representative (1̅10) surface slab consisting of two organic layers sandwiched by three inorganic slabs. Surface cations expose COOH or Br end groups in an alternating fashion. (Panel B) 3D view of (1̅10) surface further reveals nearly “stand up” cations, leading to uniform and dense coverage with dangling COOH. After water passivation, the (1̅10) surface is well protected from incoming species in the solution. (Panel C) The (221̅) surface, in drastic contrast, exhibited alternating Br or COOH terminated sections. (Panel D) 3D surface view reveals “lying down” cations due to the near-perpendicular alignment of COOH dimer with the nanowire long axis (FIG. 7, Panel A and FIG. 5). Overall, the (221̅) surface has a much-reduced surface coverage with dangling COOH and cannot be well-protected even after water passivation. The (1̅10) and (221̅) surfaces shown in (Panel B) and (Panel D) have similar cross-section areas of 1270 and 1431 Å2, respectively. Thus, illustration here presents a valid qualitative comparison of dangling COOH density. (Panel E) COOH density at each surface is calculated, where the (221̅) plane exhibits near-half COOH density compared to (1̅10). (Panel F) Optimized structure of BrCA3+H-bonded to three water molecules with a passivation energy of 3.20 eV. (G) Calculated surface energy of representative faces. Surface energy was dramatically reduced when passivated with water, leaving (221̅) the high-energy surface to drive the 1D growth.

FIG. 9 Additional SEM and AFM analysis of (BrCA3)₂PbBr₄ nanowires. (Panel A) Distinctive end facets observed in a single nanowire, including the bright field, SEM, and zoomed-in SEM images showing the distinct morphologies at the top and bottom end facets. (Panel B) SEM and AFM of a few thin and narrow nanowires: (left) SEM image with nanowire width marked. (mid) AFM height image and (right) height profile of the top-right nanowire.

FIG. 10 The expanded library of 2D and quasi-2D perovskite nanowires including (Panel A) (BrCA3)₂PbI₄, (Panel B) [SnI₄]²⁻, (Panel C) (BrCA3)₂MAPb₂Br₇ (n=2), (Panel D) (BrCA3)₂MAPb₂I₇ (n=2), (Panel E) (BrCA3)₂MA₂Pb₃I₁₀ (n=3). PL, SEM images and the PL spectra of each candidate were included. (Panel F) Longitudinal epitaxial heterostructures grown with the (BrCA3)₂PbI₄ core and bromide shell. SEM shows negligible trace of core/shell interfaces, in contrast to the easily-distinguishable Br/I interface from PL images above. Scale bar: 2 μm in (Panel A) and 10 μm in the rest.

FIG. 11 Longitudinal nanowire heterostructures examined with selective excitation and emission under confocal microscope. (Panel A) Room-temperature PL spectra of (BrCA3)₂PbBr₄ and (BrCA3)₂PbI₄ individual nanowires. (Panels B-E) Epitaxial nanowire heterostructures with iodide core and bromide shell spatially resolved by varying excitation and emission bands. In Panels B-E (i) Bright-field images; (ii) PL images with 380 nm excitation and emission over 420 nm; (iii) grey-scale PL images with 405 nm excitation and emission collected with a 593 nm bandpass filter. Both bromide and iodide components can be excited at 405 nm, but their relative emission intensity near 593 nm varied from sample to sample. For instance, (Panel Ciii) exhibits clear contrast between bromide and iodide sections due to the relatively dim emission intensity from iodide components and the more pronounced emission from the bromide shell. Panels B-E (iv) grey-scale PL images with 488 nm excitation and emission collected with a 520 nm bandpass filter. Only the excitation from the iodide components can be observed in this setting. (Panel F) PL images of the same nanowire heterostructures after a month, showing a clearly preserved Br/I interface. Scale bars: 5 μm. Data obtained at room temperature.

FIG. 12 Optical and morphological properties of nanowires of (Panel A) (FCA3)₂PbBr₄ and (Panel B) (MeCA3)₂PbBr₄. Scale bars: 10 μm. Data obtained at room temperature.

FIG. 13 Negligible linearly polarized emission from representative bromide nanowires. Scale bars: 10 μm. Data obtained at room temperature.

FIG. 14 Linearly polarized PL detected from (Panel A) a nanowire of (BrCA3)₂PbI₄ with a high DOP of 58% and propagated almost perpendicular to the long axis. (Panel B) The mechanism was revealed from a twisted nanowire showing strong emission polarization only when viewed perpendicular to its stacking direction (bottom). This twisted crystal was modeled on the right where the blue circle and the red/yellow peanuts are exact extracts from the polar graph (left), showing the varying polarization profile along the twisting action.

FIG. 15 Waveguiding (Panels A-D) and lasing (Panels E-H). (Panel A) intrinsic loss coefficients measured from a straight nanowire of (BrCA3)₂PbBr₄ and extracted from the plot of propagation-distance-dependent relative tip emission intensity. Bent (Panel B) and twisted (Panel C) nanowires were examined, showing low loss coefficients as well. (Panel D) A pair of cross-coupled nanowires excited at the horizontal waveguide from left or right of the intersection. (Panel E) A representative nanowire of (BrCA3)₂SnI₄ pumped above the threshold at 88 K, showing majority emission from the two end facets with coherent interference patterns. (Panel F) Emission spectra of the stimulated lasing (red) versus the spontaneous emission (grey). (Panel G) Threshold behavior examined from integrated outcoupled emission plotted against the pump fluence. (Panel H) Mode distance against the reciprocal nanowire length examined from a series of lasing nanowires, which was fitted according to Fabry-Perot modes. (scale bars: 10 μm).

FIG. 16. Two representative coupled nanowire waveguides made of (BrCA₃)₂PbBr₄ with tip-tip joint. (Panel A) Tightly coupled case with touching tips (Panel A-iii) where light transport to adjacent crystal is efficient: (Panel A-v) shows the excitation from bottom-right segment and transport to the top-left, and vice versa in (Panel A-vi). Directional light transport was observed at the joint section as magnified in the two insets. For instance, clear light transport from bottom-right to top-left was detected when only the bottom-right crystal was excited, which was negligible from top-left to bottom-right. (Panel B) Two loosely coupled waveguides where light outcoupled from the bottom crystal could not be efficiently transport to the top-right one. Detailed information of each image: (i) bright field image; (ii) SEM image of the entire structure; (iii) SEM image of the joint marked as white dashed square in (i and ii); (iv) PL image with homogenous excitation; (v and vi) PL image with laser excitation on selected areas. Scale bars: 1 μm in (iii), 10 μm in others. Data obtained at room temperature.

FIG. 17. Progression of lasing. PL spectra and images with increasing pump fluence across the threshold of the (BrCA3)₂SnI₄ nanowire examined in FIG. 15, Panels E-G (Pth: 16.96 μJ/cm2).

FIG. 18. Mode distance analysis. Bright-field images of five representative nanowires of (BrCA3)₂SnI₄ with varying length involved in the mode spacing analysis in FIG. 15, Panel H. PL images below and above threshold, and the lasing spectra above threshold are displayed as well.

### DETAILED DESCRIPTION

Before the present methods, implementations, and systems are disclosed and described, it is to be understood that this disclosure is not limited to specific synthetic methods, specific components, implementation, or to particular compositions, and as such may, of course, vary. It is also to be understood that the terminology used herein is for the purpose of describing particular implementations only and is not intended to be limiting.

As used in the specification and the claims, the singular forms “a, “an” and “the” include plural references unless the context clearly dictates otherwise. Ranges may be expressed in ways including from “about” one particular value, and/or to “about” another particular value. When such a range is expressed, another implementation may include from the one particular value. Another implementation may include from the one particular value and/or the other particular value. Similarly, when values are expressed as approximations, for example by use of the antecedent “about,” it will be understood that the particular value forms another implementation. It is to be understood that the use of the term “about” indicates that the value cited may include a range of + or −5 to 50% of the cited value. It will be further understood that the description includes instances where said event or circumstance occurs and instances where it does not.

Several non-limiting embodiments of the disclosure are recited in the clauses listed below.

1. An elongated single crystal layered halide perovskite nanowire with formula II

(A)₂PbX₄ (II)
wherein A is an organic ammonium salt selected from the group consisting of 2-(2,5-dicarboxyphenoxy) ethan-1-aminium (TPA3), 2-(2-bromo-5-carboxyphenoxy) ethan-1-aminium (BrCA3), 2-(5-carboxy-2-fluorophenoxy) ethan-1-aminium (FCA3), and 2-(5-carboxy-2-methylphenoxy) ethan-1-aminium (MeCA3); and X is Br or I.

2. The elongated single crystal layered halide perovskite nanowire of clause 1, wherein X is Br.

3. The elongated single crystal layered halide perovskite nanowire of clause 1, wherein X is I.

4. The elongated single crystal layered halide perovskite nanowire of clause 2, wherein A is TPA3.

5. The elongated single crystal layered halide perovskite nanowire of clause 2, wherein A is BrCA3.

6. The elongated single crystal layered halide perovskite nanowire of clause 2, wherein A is FCA3.

7. The elongated single crystal layered halide perovskite nanowire of clause 2, wherein A is MeCA3.

8. The elongated single crystal layered halide perovskite nanowire of clause 3, wherein A is TPA3.

9. The elongated single crystal layered halide perovskite nanowire of clause 3, wherein A is BrCA3.

10. The elongated single crystal layered halide perovskite nanowire of clause 1, comprising straight or bent nanowire of (BrCA3)₂PbBr₄, wherein the elongated single crystal layered halide perovskite nanowire has a maximum length up to 100 μm, a mean length of about 8.45 μm, and a mean diameter/width of about 400 μm.

11. A waveguide comprising the elongated single crystal layered halide perovskite nanowire of clause 10 with nanowire length of about 50 to about 100 μm and wherein the intrinsic light transport optical loss coefficient is about 2.7 dB/mm.

12. A single crystal layered halide perovskite nanowire laser comprising nanowires of (BrCA3)₂SnI₄, prepared by the method of clause 26, wherein the single crystal layered halide perovskite nanowire laser has a light amplification threshold at 88 K is below 20 ρJ/cm².

13. An elongated layered halide perovskite nanowire heterostructure comprising an elongated (BrCA3)₂PbI₄ core; and an elongated (BrCA3)₂PbBr₄ shell surrounding and encapsulating the elongated (BrCA3)₂PbI₄ core.

14. A method of making an elongated single crystal layered halide perovskite nanowire with formula I

(A)₂(CH₃NH₃⁺)ₙ₋₁MₙX₃ₙ₊₁ (I)
wherein A is an organic ammonium salt selected from the group consisting of 2-(2,5-dicarboxyphenoxy) ethan-1-aminium (TPA3), 2-(2-bromo-5-carboxyphenoxy) ethan-1-aminium (BrCA3), 2-(5-carboxy-2-fluorophenoxy) ethan-1-aminium (FCA3), and 2-(5-carboxy-2-methylphenoxy) ethan-1-aminium (MeCA3); M is a divalent metal cation, where the metal is Pb or Sn; X is Br or I, and n is 1, 2, or 3;
the method comprising the steps of:
a) preparing an aqueous working mixture of HX, MX₂, and A, with the proviso that when X is I, the working mixture also includes H₃PO₂;
b) optionally adding CH₃NH₃⁺X⁻ to the working mixture to yield an n>1 nanostructure;
c) optionally adding dimethylformamide (DMF) to the working mixture to obtain structures with n>1 and X=Br;
e) heating the working mixture of step d) to above 100° C. to induce mild refluxing of the working mixture to dissolve any undissolved components of the working solution to yield a clear working solution;
f) optionally applying sonication to the working solution of step e) to assist the dissolution;
g) holding the clear working solution at about 90° C. to ensure no precipitate formation;
h) fast-cooling the clear working solution from about 90° C. to 20° C. over a period of time, wherein the period of time is between 5 to 10 minutes to yield a plurality of elongated, single crystal layered halide perovskite nanowires with nano or micro-sized diameters;
i) optionally extracting a droplet of the clear working mixture at an adjustable temperature from about 40° C. to about 70° C. and rapidly cooling the droplet by placing it on a surface in room temperature air to yield a plurality of elongated, single crystal layered halide perovskite nanowires optionally grown at the droplet-air interface; and
j) optionally transferring the single crystal layered halide perovskite nanowires obtained in optional step i) onto the surface of a substrate selected from the group consisting of polydimethylsiloxane (PDMS), glass, quartz, and a silicon wafer.

15. The method of clause 14, wherein M is Pb.

16. The method of clause 14, wherein M is Sn.

17. The method of clause 15, wherein X is Br.

18. The method of clause 15, wherein X is I.

19. The method of clause 16, wherein X is I.

20. The method of clause 17, wherein A is TPA3.

21. The method of clause 17, wherein A is BrCA3.

22. The method of clause 17, wherein A is FCA3.

23. The method of clause 17, wherein A is MeCA3.

24. The method of clause 18, wherein A is TPA3.

25. The method of clause 18, wherein A is BrCA3.

26. The method of clause 19, wherein A is BrCA3.

To address the above-referenced limitations of the prior art, disclosed is a new and generalizable “molecular clamp” approach to break the 4-fold symmetry and regulate one-dimensional (1D) growth of two-dimensional (2D) perovskites via secondary bonding interactions. Specifically, in-plane hydrogen bonding, which is simultaneously compatible with the ionic nature and octahedron spacing of halide perovskites, is introduced. With specific molecular engineering, nanowires of 2D halide perovskites were readily assembled in solution facilitated by the formation of 1D H-bonding network in the organic layer. These nanowires with editable lengths and high-quality cavities provided an ideal platform to study anisotropic excitonic behaviors, light propagation, and amplification within 2D halide perovskites. This approach highlights the unique structural tunability of organic-inorganic hybrid semiconducting materials by synergizing the merits of each, which also brings unprecedented opportunities to 2D materials.

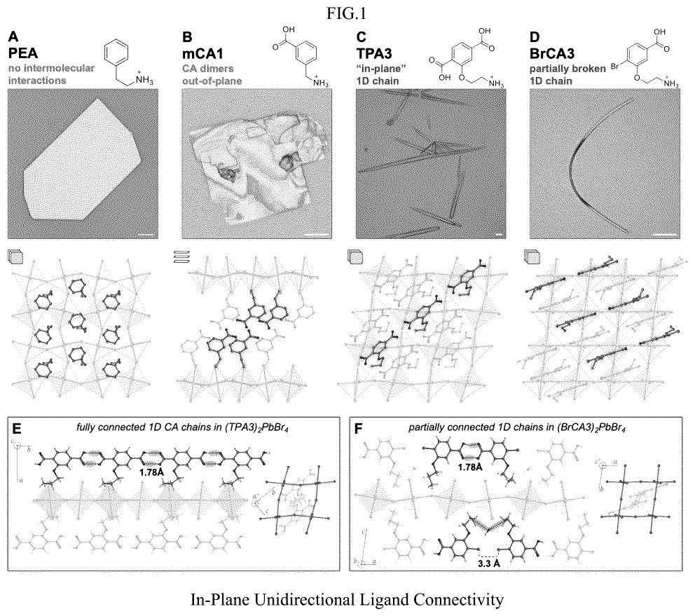

FIG. 1 shows a comparison among the morphologies and crystal structures of 2D [PbBr4]2-perovskites based on various organic cations: (Panel A) PEA, phenylethylammonium, (Panel B) mCA1, (3-carboxyphenyl) methanaminium, (Panel C) TPA3, 2-(2,5-dicarboxyphenoxy) ethan-1-aminium, and (Panel D) BrCA3, 2-(2-bromo-5-carboxyphenoxy) ethan-1-aminium. The middle panels show the morphology of individual crystals obtained with the floating growth method (see METHODS) examined with bright-field optical microscopy (scale bars: 10 μm). Bottom panels highlighted the arrangement of organic cations in the structures of each 2D perovskites viewed along their stacking directions, except in (mCA1)₂PbBr₄ scenario, which was viewed perpendicular to its stacking direction due to CA dimer formation across the Van der Waals gap. Hydrogens were omitted for clarity. (Panel E) and (Panel F) further examined the 1D CA dimer chains observed in crystal structures of TPA3 and BrCA3-based 2D perovskites, respectively, and the out-of-plane examination of octahedral tilting. Cell axes shown in (Panel E) and (Panel F) only represents the approximate length and angle.

Contemporary organic cations designed for 2D perovskites typically impose limited long-range order. For example, an out-of-plane view along the stacking direction of (PEA)₂PbBr₄ reveals a classical herringbone packing motif in the organic layer (FIG. 1, Panel A), leading to self-assembled thin sheets (here, out-of-plane and in-plane correspond to the crystallographic planes in anisotropic 2D perovskites). In order to align the cations, carboxylic acid (COOH) was chosen to form robust dimer structure via multiple H-bonds, which are known for their strong directionality widely employed to drive the self-assembly and alignment of organic building blocks. The COOH attachment to the 3-position of the phenyl ring resulted in formation of classical COOH dimers out-of-plane across the van der Waals gap (as shown in FIG. 1, Panel B with the modified cation mCA1), which has been previously observed in 2D perovskites. Albeit useful to intercalate secondary lattices by exploiting the chelating capabilities of carboxylates. it failed to transfer its directionality to the in-plane growth of 2D perovskite crystals and only 2D sheets/flakes are obtained.

To direct 1D growth, it was attempted to align the H-bonds with inorganic slabs. An additional COOH unit was introduced in the para position of the existing moiety, forming a backbone that resembles terephthalic acid (TPA). The new candidate was named TPA3 accordingly FIG. 1, Panel C). Crystal structure of (TPA3)₂PbBr₄ unveiled the well-aligned parallel “1D chains” of TPA3 on top of 2D inorganic slab driven the robust unidirectional intermolecular interactions (FIG. 1, Panel C). To adopt the size of COOH dimers, adjacent TPA moieties were connected along the crystallographic direction with a spacing of 9.54 Å characterized by the aromatic centroid distance. Each 1D chain consists of periodic COOH dimers with an average H-bonding distance of 1.78 Å. Surprisingly, this unidirectional in-plane connectivity in the organic layer led to the self-assembly of 2D halide perovskites into needles and wires with high aspect ratios, which happened spontaneously by cooling a saturated hot precursor solution. In other words, the directionality observed in the organic layer could, to some extent, influence the orientation control of the assembled halide perovskites.

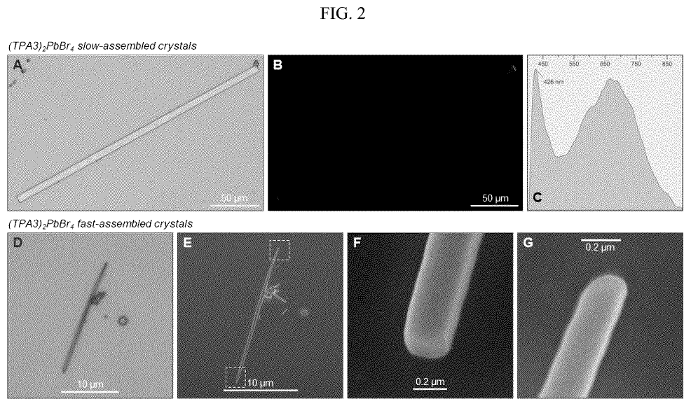

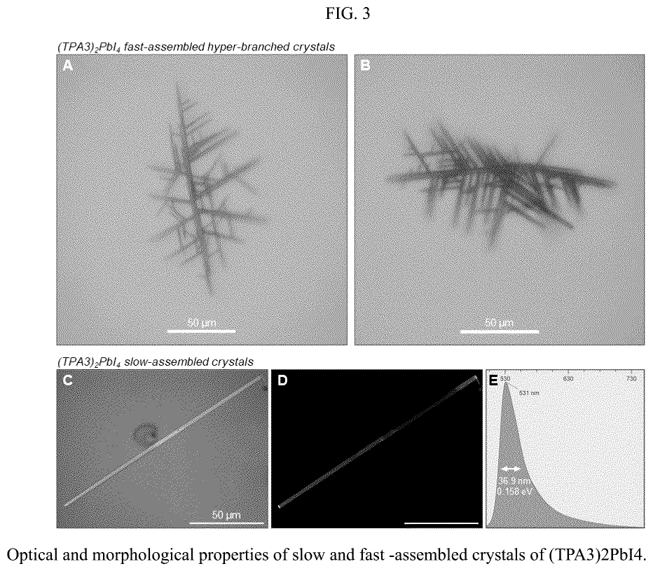

However, TPA3-based 2D perovskites exhibited several unsatisfactory morphological and optical properties. Achieving high-quality crystals (FIG. 2, Panels A-B) demands a very slow self-assembly process, whereas fast growth usually led to poorly defined end-facets (FIG. 1, Panel C and FIG. 2, Panels D-G), branched, or even hyperbranched crystals observed in the case of (TPA3)2PbI4 (IG 3, Panels A-B). Optically, (TPA3)2PbBr₄ exhibited negligible excitonic emission even from its slow-assembled single crystals followed by a considerable broad band, which usually result from self-trapped excitons or in-gap defect states (FIG. 2, Panels B-C). The iodide counterpart also presented broad excitonic emission (FIG. 3, Panels C-E). It was hypothesized that the establishment of strong H-bonding disrupted the assembly of ionic species, leading to extensive formation of defects during crystal growth and further driving the hyperbranching behavior. The accommodation of COOH dimers also resulted in a considerable degree of octahedral tilting and lattice distortion (FIG. 1, Panel E), which is commonly associated with quenched excitonic feature and broadband emission. These characteristics from TPA3-based 2D perovskites may discourage their miniaturizing into nanostructures.

### Partially Broken 1D Chain

To balance non-covalent H-bonding with ionic assembly, the 1D H-bonding network was partially disrupted by substituting one COOH unit in the TPA backbone with bromine, which acted as a structuring unit to prevent COOH dimers from being twisted back to form interlayer H-bonds. Surprisingly, the new candidate, BrCA3, can maintain a similar in-plane connectivity and form parallelly aligned “partially broken” 1D chains on top of inorganic slabs (FIG. 1, Panel D), which are now parallel to the crystallographic direction but deviated from either the zigzag or the armchair direction of octahedrons. Octahedral tilting and lattice distortion are therefore reduced presumably due to the relieved stress in the H-bonding network (FIG. 1, Panel F). A closer look at each chain reveals pairs of BrCA3 recognized through COOH dimers with the same H-bonding and centroid distance as those in the TPA3 counterpart (FIG. 1, Panel F). On the other end, adjacent molecules are well separated with an intermolecular Br—Br spacing of 3.30 Å. Unexpectedly, water molecules occupied the “cavities” created by adjacent BrCA3 molecules on their bromine ends, which might be introduced through H-bonding with ammonium tails. Considering the hygroscopic nature of halide perovskites, this partial occupancy of water is rather unusual.

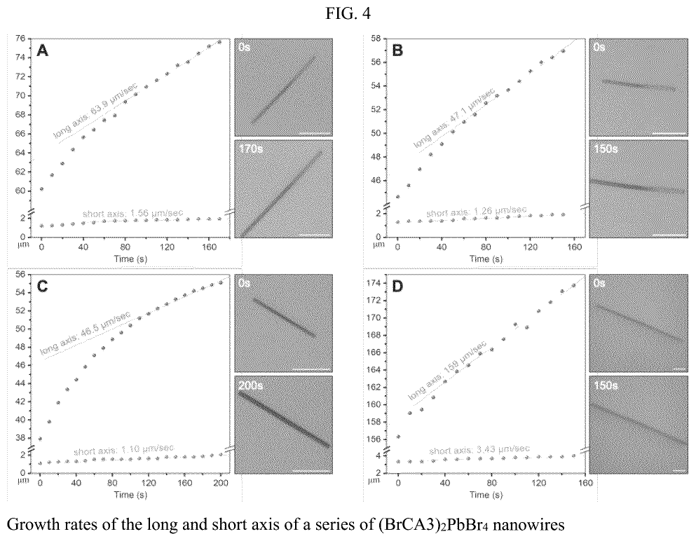

Remarkably, the partially broken 1D connectivity introduced by BrCA3 promoted balanced and rapid self-assembly of 2D perovskites with exceptionally large aspect ratios. These crystals could be further miniaturized into high-quality nanowires via accelerated crystal assembly at the solution-air interface, a type of floating growth method originally developed (D. Pan et al., Nat. Nanotechnol. 16, 159-165 (2021).) for 2D perovskites with sheet morphologies. FIG. 1, Panel D presented a characteristic nanowire of (BrCA3)₂PbBr₄ with an aspect ratio over 100 (ca. 80 μm long, 0.7 μm wide), well-defined end-facets, and an intriguing twisted morphology to be further investigated. The in situ nanowire growth was further examined, revealing an approximately 40-times faster growth along its long axis compared with that along the short axis (FIG. 4).

The discovery of 2D perovskite nanowires using BrCA3 motivated investigation of their distinctive morphological, physical, optical features, and most importantly, the growth mechanism of these nanowires involving the synergistic effects of organic intermolecular interactions and ionic self-assembly.

Morphological Control with “Molecular Clamps”

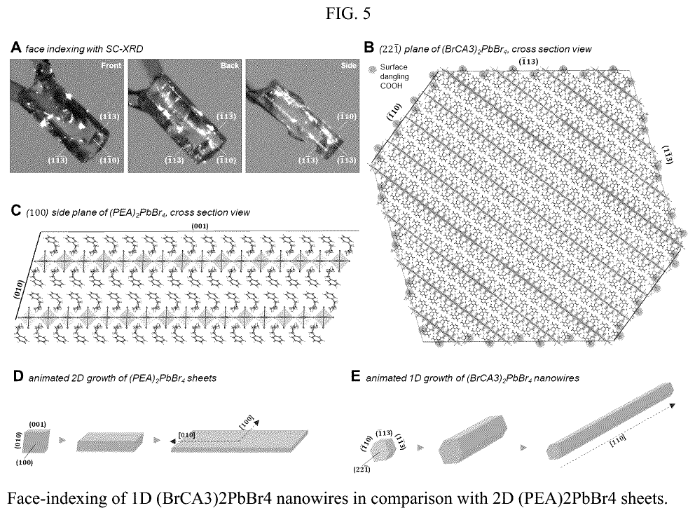

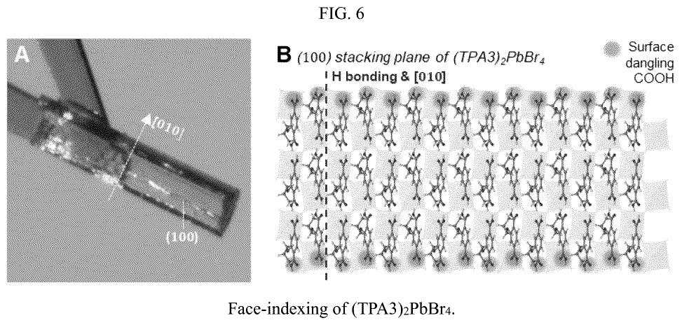

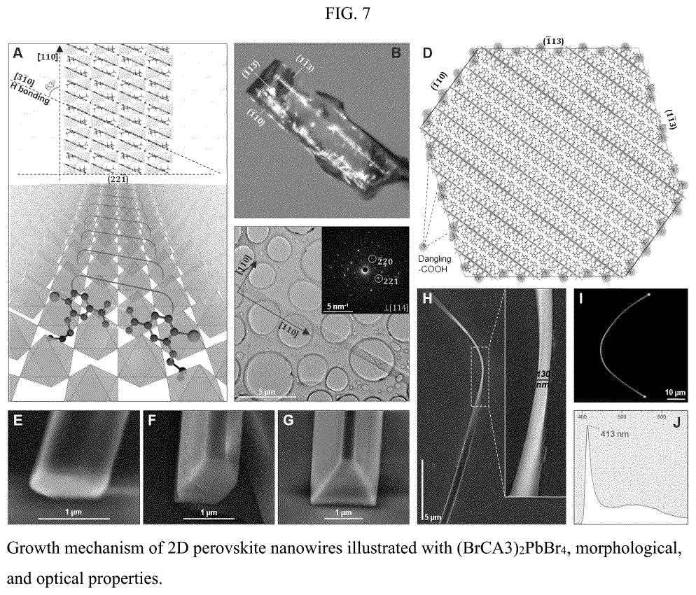

While the morphological control of 2D halide perovskite nanowires seems to inherit the 1D connectivity of organic cations, it remains a question whether their growth direction actually follows the H-bond direction created by COOH dimers. To answer this question and unveil the nanowire growth mechanism, single-crystal X-ray diffraction (SC-XRD) and selected-area electron diffraction (SAED) were conducted to face-index bulk crystals and nanowires of (BrCA3)₂PbBr₄, respectively FIG. 7, Panels A-C and FIG. 5). Results unequivocally aligned the long axis of each crystal with its crystallographic direction and the short axis to [11̅0], both of which align with the zig-zag stacking direction of [PbBr₄]²⁻ octahedrons. The COOH dimers (along [310]), surprisingly, exhibit a substantial angle of 63° relative to the long axis, which seems to suggest a conflicting role in promoting 1D growth. The dimer orientation in the TPA3 counterpart, on the other hand, is exactly perpendicular to the long axis of its growth direction according to its face-indexing results (FIG. 6), which clearly contradicts with the initial intuitive hypothesis that nanowires would grow along the directional H-bonds.

Unexpectedly, the COOH dimers act as “molecular clamps”, hindering rather than facilitating the growth of 2D perovskites. This intriguing phenomenon may arise from a combinatory effect of the 1D H-bonding network and the surface-protective attributes of carboxylic acids. The alignment of cations correlates with the distinctive exposure of COOH moieties at the side versus the end facets (here, side facets refer to all the faces that are parallel to the long axis). For instance, the crystal investigated under SC-XRD exhibited six side faces indexed as (1̅10), (1̅13), (11̅3), and their parallel counterparts where (1̅10) lies perpendicular to the [11̅0] short axis identified via SAED (FIG. 7, Panels B-D). Notably absent is the (001) face parallel to [PbBr₄]²⁻ slabs, which was typically observed in conventional 2D perovskites but instead subdivided into (1̅13) and (11̅3). A cross-sectional view of the end facet along [110] reveals a pronounced occupancy of dangling COOH moieties on each side facet (FIG. 7, Panel D) due to a near-perpendicular H-bonding alignment with the long axis, (FIG. 7, panel A). In particular, “splitting” (001) into (1̅13) and (11̅3) enhances the surface-exposure of COOH.

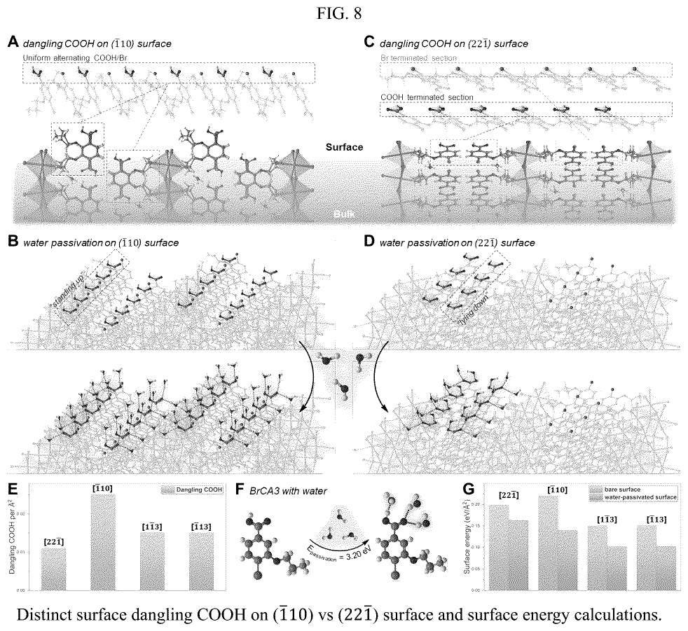

These findings suggested that surface dangling carboxylic acids would slow down crystal growth and lead to the preferred exposure of COOH-abundant surfaces. While it seems to be counter-intuitive, the behavior actually resembles previously reported polymer-assisted synthesis of oxide perovskite Pb(Zr/Ti)O₃ nanowires (G. Xu et al., Adv. Mater. 17, 907-910 (2005).), where polymer was hypothesized to reduce the surface tension of certain crystallographic planes. The nanowire growth was thus driven by the coverage of high-energy exposed surfaces and left them as end facets. In the system, surface dangling carboxylic acids protect nanowire side faces by forming robust H-bonds with aqueous solvent molecules, like water. Incoming cations therefore need to break the existing protective H-bonds and overcome steric hinderance. This effect becomes particularly weaker at the (221̅) end facet. As illustrated in FIG. 8, the (1̅10) side face exhibits uniform coverage with dangling COOH, while the surface COOH density at (221̅) is nearly halved, making it insufficiently protected from incoming cations even after water passivation. The surface energies of notable faces was further calculate by density functional theory (DFT). Indeed, considerable anisotropy was observed after considering the effects from water passivation, leading to higher surface energy at the (221̅) facet (FIG. 8). Accordingly, the mysterious molecular clamp mechanism was elucidated, which involves the synergistic effect of CA dimers to direct the alignment of organic cations, drive the anisotropic surface termination of dangling CA moieties, and protect these surfaces through robust H-bonding with solvent molecules.

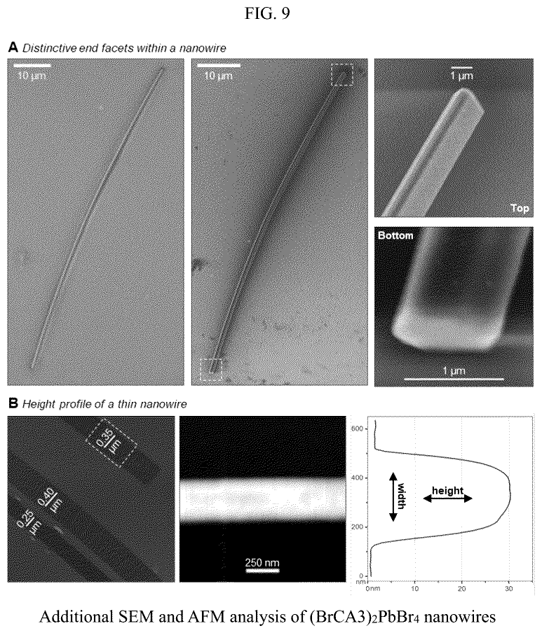

The discussion above demonstrated a unique mechanism to achieve morphological control in hybrid 2D perovskites by simultaneously employing directional molecular clamps consisting of CA dimers to drive 1D growth and strategically using partially broken 1D chains to achieve balanced growth conditions. These observed merits highlight the surprising tunability of organic-inorganic hybrid semiconductors and culminate in the formation of nanowires with exceptional crystal quality reflected in their well-defined end-facets. While the hexagonal cylindrical crystal investigated in SC-XRD presented one possibility, miniaturized nanowires of (BrCA3)₂PbBr₄ displayed diverse morphologies commonly observed as hexagonal or acute trapezoidal end facets (FIG. 7, Panels D-F). The interplay among side faces can lead to distinct termination morphology even within the same nanowire (FIG. 9, Panel A). These intricate morphological features likely stem from the surface-modification with dangling CA moieties, providing a range of low-energy faces to be exposed. Notably, narrow and thin crystals (ca. 30 nm) also exhibited smooth terminations (FIG. 9, Panel B). These thin nanowires easily bend or twist as shown in FIG. 7, Panel G demonstrating the 1800 twisting of a nanobelt. Optically, (BrCA3)2PbBr4 crystals exhibit white photoluminescence (PL) at room-temperature consisting of a sharp excitonic peak at 413 nm and a lower energy broad emission band (FIG. 7, Panels I and J). The PL characteristics were well-inherited in nanowires of (BrCA3)2PbBr4 and remained unaffected by their bending or twisting actions.

### An Expanded Library of 2D Perovskite Nanowires

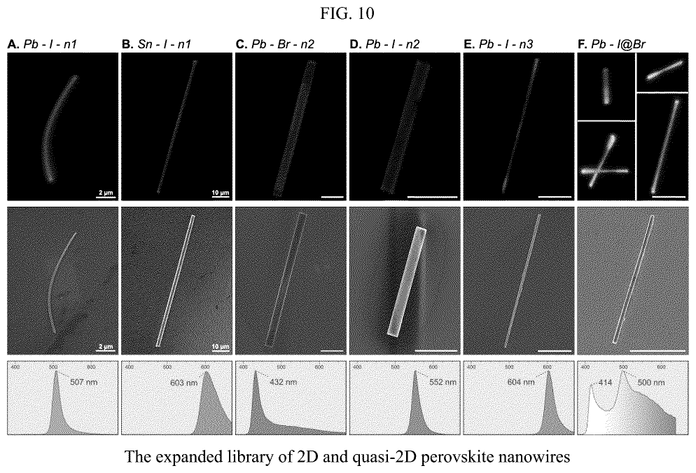

The “molecular clamp” mechanism featuring directional CA dimers is generally applicable to a wide-range of low-dimensional perovskites with diverse tunability from both organic and inorganic perspectives. For example, BrCA3-based nanowires with [PbI₄]²⁻ and [SnI₄]²⁻ matrices were readily obtained (FIG. 10, Panels A-B); high aspect ratio was also generally achievable in quasi-2D perovskites such as n=2 in lead-bromide matrix (BrCA3)2MAPb2Br7 (FIG. 10, Panel C) and n=2 and n=3 in lead-iodide counterparts (FIG. 10, Panels D-E).

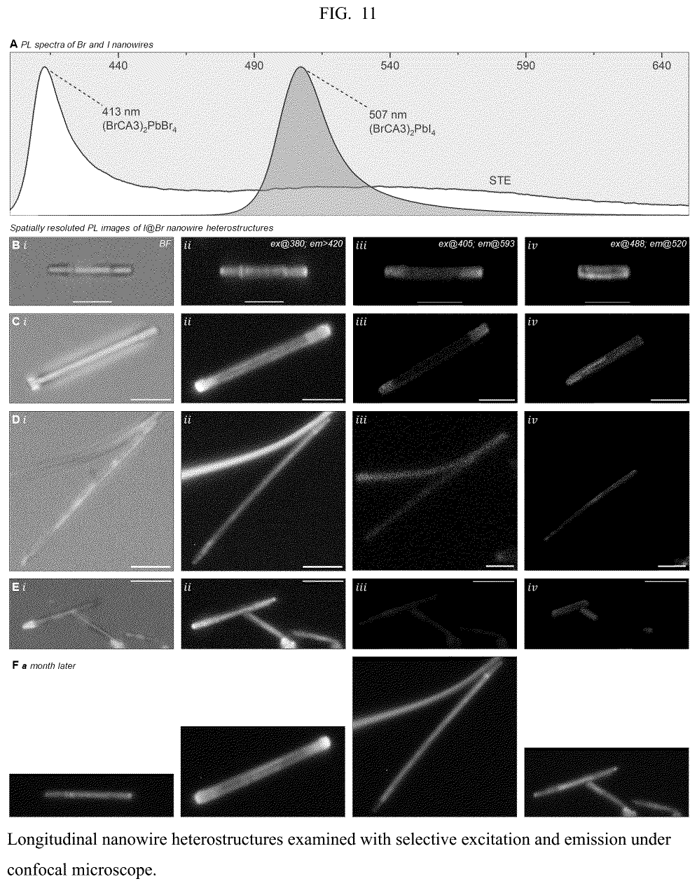

Surprisingly, epitaxial growth of these nanowires originates preferably from their end facets. FIG. 10, Panel F exhibited a few representative di-block or tri-block longitudinal heterostructures obtained with deliberate fast nucleation of (BrCA3)2PbBr4 nanowires on the as-grown iodide cores (METHODS). While interface between core and shell is morphologically indiscernible (FIG. 10, Panel F), longitudinal extension of bromide segments could be conspicuously distinguished by its distinct white PL, while co-axial growth around the side faces of iodide cores remained negligible. Enhanced core/shell resolution was further achieved via selectively exciting bromide or iodide sections (FIG. 11, Panels B-E). Our demonstration introduced the first longitudinal epitaxial nanowire heterostructure within organic-inorganic hybrid semiconducting materials. In contrast to those synthesized with 3D halide perovskites with a gradient ion distribution, nanowire heterostructures based on 2D halide perovskites offered amplified stability against halide migration which gave rise to their stable interface preserving clear Br/I contrast (FIG. 11, Panel F). In this system, the preferable shell nucleation from the end facets is likely another distinctive feature facilitated by the abundant protective dangling CA moieties on the side faces, which shield the as-grown crystals against the nucleation of additional layers. In this regard, these candidates also distinguish themselves from the epitaxial heterostructures of III-V semiconductors nanowires via seeded growth.

From the perspective of organic cations, the design of BrCA3 can be expanded by facile replacement of bromide with other structuring units such as fluorine or methyl. These new candidates can sustain the one-dimensional growth of 2D perovskite nanowires, as illustrated with their [PbBr4]2− derivatives (FIG. 12). Optically, compared with (BrCA3)₂PbBr₄, the broad emission band is slightly lower in the fluorine but significant higher in the methyl counterpart, resulted in bluish-white and yellowish-green emission, respectively. While broadband emission hampers the color purity, it also facilitates color tunability in 2D perovskite nanowires with subtle variation of organic cations. This can be potentially useful to create multi-color nanowire heterostructures to use in photonic applications.

### Unusual Optical Properties

### Heterogenous Emission Polarization in a Single Nanowire

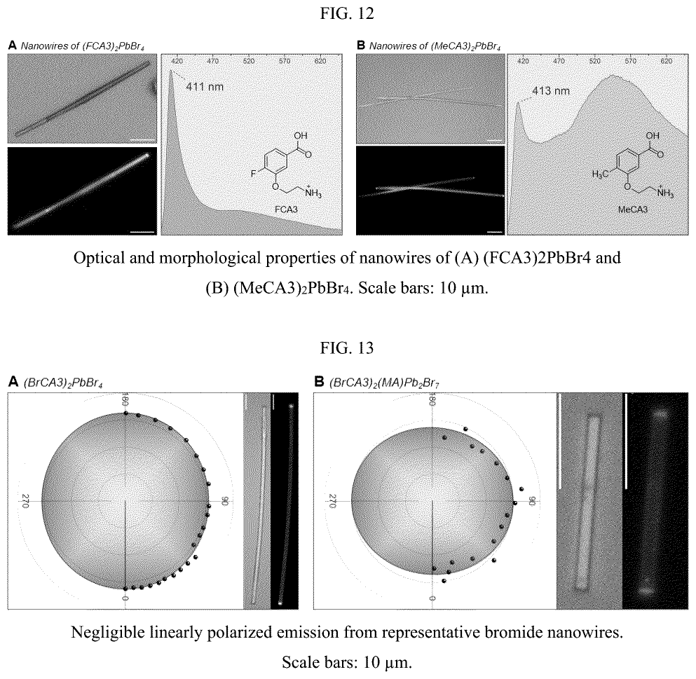

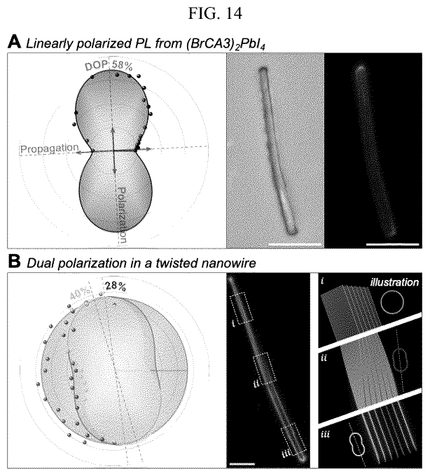

Morphologically restricting the growth of 2D perovskites into 1D nanowires facilitates the investigation of distinctive optical properties along or perpendicular to the stacking directions of these layered structures. It was initially observed that PL from nanowires of (BrCA3)₂PbBr₄ and (BrCA3)₂MAPb₂Br7 displayed weak linear polarization that approximately propagated along their long axes (FIG. 13); this has been generally attributed to the anisotropic confinement of electric field within high aspect ratio nanostructures. On the stark contrary, iodide counterparts typically exhibited strong polarization dependence. A 58% degree of polarization (DOP) was observed from a representative candidate of (BrCA3)2PbI4 (FIG. 14, Panel A) with emission propagated almost perpendicular to its long axis, however, which directly contradicted our previous observations.

2D perovskites possess intrinsic emission polarization due to the in-plane confinement of excitons. While such phenomenon is challenging to observe in contemporary 2D perovskites with stacking direction typically parallel to the substrates, nanowires offer ready accessibility to their side facets. Therefore, when viewing perpendicular to the stacking direction, strong linearly polarized PL could be revealed which propagates perpendicular to the long axes, corresponding with the observation from nanowires of (BrCA3)₂PbI₄.

More interestingly, a piece of twisted (BrCA3)₂PbI₄ nanowire was examined to unequivocally resolve the origin of its polarization dependence (FIG. 14, Panel B). Twisting allows the observation of both in-plane and out-of-plane optical properties within a single nanowire. As illustrated subsequently, inorganic slabs were originally stacked parallel to the substrate at the top half of the crystal but gradually twisted to allow the view perpendicular to its stacking direction. The twisting action created diverse linearly polarized PL within the same crystal, which could be further quantified and spatially resolved. While emission polarization was negligible at the top, the crystal gradually exhibited linearly polarized emission with slowly rotated polarization direction along the twisting action, resulted in a DOP of 40% at the bottom. To the best of our knowledge, this is the first demonstration of heterogenous emission polarization from a single semiconductor nanowire, owning to the unique combination of 2D crystal structure, 1D growth kinetics, and the twisted nanowire morphology.

### Active Waveguides and Lasing

While the intrinsic anisotropic excitonic properties of 2D halide perovskites was revealed via morphological control, miniaturized nanowires also create unique cavities to study their light propagation behavior. In this regard, nanowires of our 2D perovskites are exceptional candidates for active waveguides inspired by their editable length, emission tunability, and bendable morphology. Waveguide losses were assessed from a few ca. 100 μm long nanowires of (BrCA3)₂PbBr₄ according to their propagation-distance-dependent relative tip emission intensity collected and analyzed with far-field PL images (METHODS). Nanowires of (BrCA3)2PbBr4 exhibited intrinsic loss coefficients as low as 2.7 dB/mm as observed in straight candidates (FIG. 5, Panel A), which outperform the contemporary inorganic and organic (Y. Li et al., ACS Appl. Mater. Interfaces 9, 8910-8918 (2017).) semiconductor waveguides. Narrow and bent nanowires (FIG. 5, Panel B), or even strongly twisted ones (FIG. 5, Panel C), possessed similar losses to wide and straight waveguides owing to the sustained crystal quality under bending or twisting actions. These characteristics suggest their promising application in miniaturized photonic and optoelectronic devices.

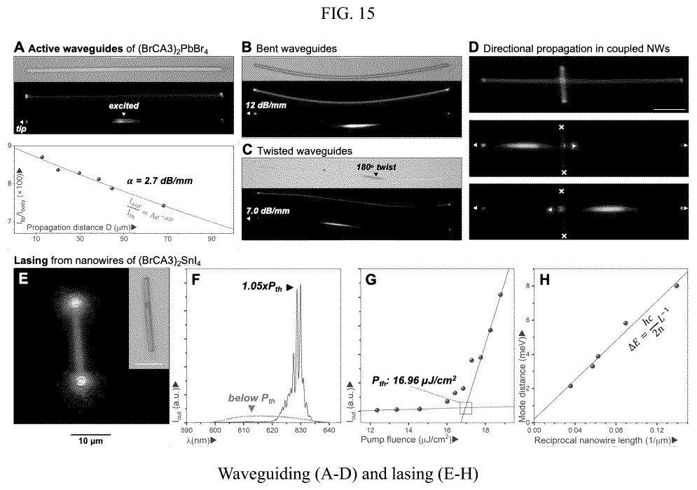

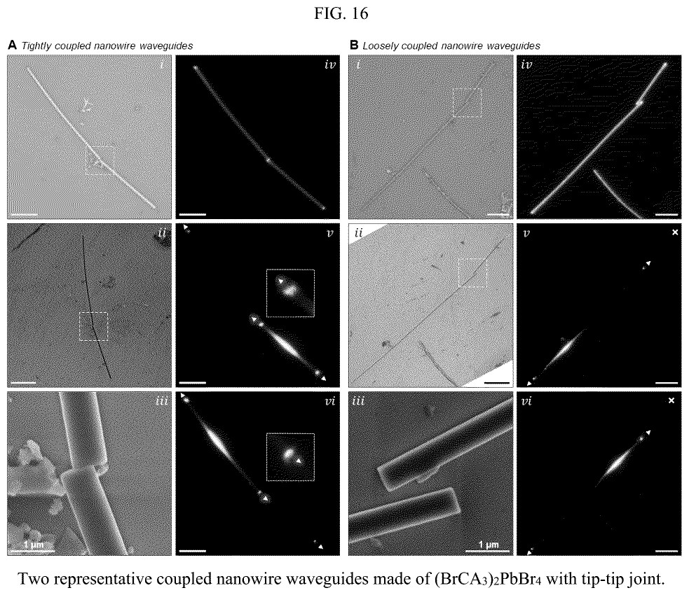

Furthermore, waveguides can be coupled and transport light to adjacent crystals, creating complex optical network. A few coupled nanowires were examined through tip-tip interactions or cross-intersections (FIG. 15. Panel D and FIG. 16), demonstrating proof-of-concept potentials to construct more intricate optical networks. The directional propagation of light within one-dimensional nanowires needs to be strictly observed to ensure efficient communication between couple waveguides. FIG. 15. Panel D examined a perpendicular pair of cross-coupled waveguides creating a “crossroad” intersection and multiple scattering sites. Due to the one-dimensional propagation of light, only the right end of the intersection could be illuminated when fluence was injected from the left side of the intersection, and vice versa. On the contrary, minimum outcoupled light could be detected from the vertical nanowire since light was injected from the horizontal crystal.

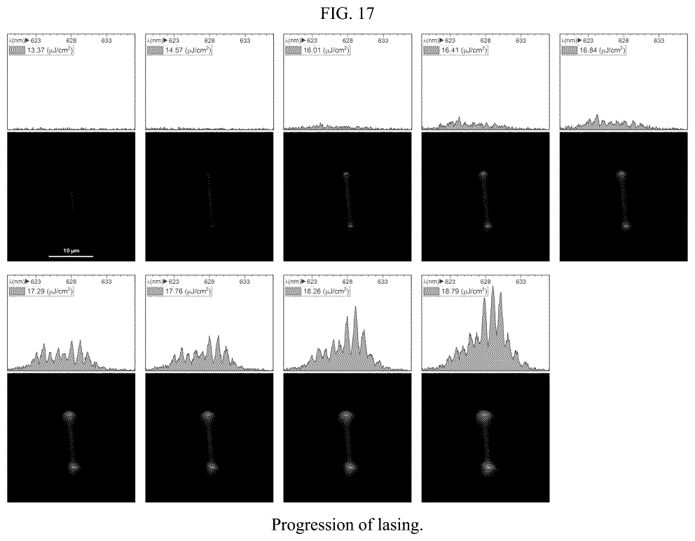

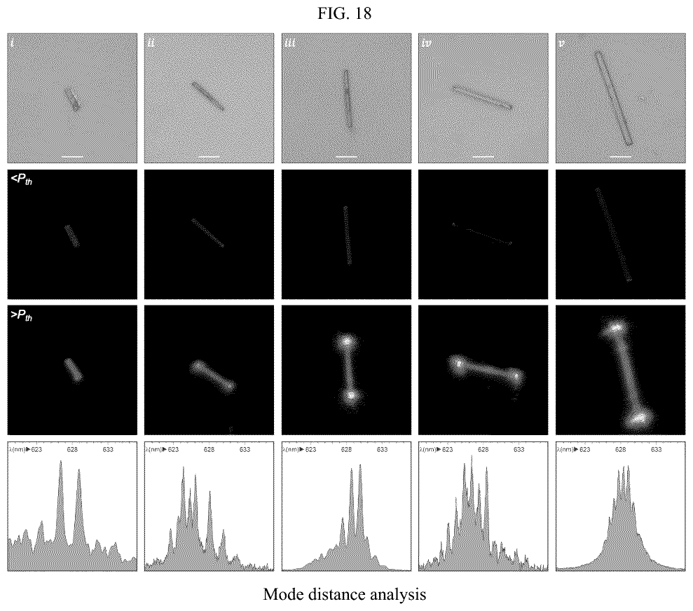

The low-loss waveguiding behavior of BrCA3-based 2D perovskite nanowires suggested their promise as Fabry-Perot cavities for optical amplification. Building on the pioneering efforts on semiconductor nanowire lasers and subsequent lasing in 3D perovskites, the lasing behavior of BrCA3-based 2D perovskite nanowires was investigated. In lead-based 2D halide perovskites, lasing threshold is often constrained by the strong exciton-phonon interaction or Auger recombination. Enhanced lasing performances are commonly pursued in quasi-2D systems. Tin-based 2D halide perovskites, on the other hand, may exhibit lasing performances surpassing their lead counterparts, as shown in recent studies on thin films and exfoliated crystals. However, their lasing threshold are still pinned in the ˜100 ρJ/cm² regime with significant sample-to-sample variation, both due to the lack of well-established cavity. To examine the lasing potential of our materials, nanowires of (BrCA3)₂SnI₄ were investigated. Interestingly, emission from the two end facets gradually took dominance with increasing pump fluence (FIG. 17), which was accompanied by the appearance of spatially interference patterns (FIG. 15, panel E) and multi-mode lasing at the lower-energy end of the spontaneous emission band (FIG. 15, panel F). Clear threshold behavior was observed by monitoring the integrated emission intensity across the threshold, giving a lasing threshold of 16.96 mJ/cm² (FIG. 15, panel G), which is remarkably lower than contemporary tin-based 2D perovskites. The bright localized emission from the tips and multi-mode lasing from this relatively long nanowire (ca. 16.0 mm) are both consistent from the strong waveguiding behavior under Fabry-Perot modes. To confirm this, mode spacing (DE) was analyzed from a series of nanowires with varying lengths (L), which decreased with L and observed a linear trend with the reciprocal nanowire length (1/L), confirming the Fabry-Perot cavity characteristics (FIG. 15, Panel H and FIG. 18).

### Discussion

2D perovskite nanowires based on BrCA3 have displayed a diverse array of unusual optical properties. On one aspect, the intrinsic exciton behavior of 2D halide perovskites enables facile observation and control of polarized emission. Concurrently, these nanowires also revealed exceptional cavity qualities, thereby fostering active waveguides with low loss coefficients and facilitating light-amplification with notable low thresholds.

The method to manipulate the morphology of 2D halide perovskites by introducing robust intermolecular interactions between organic cations is distinctive to the special crystal structures of organic-inorganic hybrid materials and requires more comprehensive investigations. As disclosed herein, the CA dimer was originally exploited to enforce one-dimensional orientation within the organic layer. Nevertheless, this type of directionality appears to hamper rather than facilitate the 1D growth of 2D perovskites, which complicated the establishment of morphological control in an unforeseen manner. However, through an examination of side and end facets, the synergistic role of CA dimers was discovered, which simultaneously created aligned organic cation network and therefore protected side surfaces with dangling CA moieties. While 1D nanowire growth can be achieved through this molecular clamp mechanism, achieving optimal optical and morphological properties requires more delicate molecular engineering to promote balanced and rapid self-assembly of 2D perovskites into miniaturized nanowires. In this context, TPA3 was replaced by BrCA3 with partially broken 1D chains of CA dimers.

Morphological control with directional supramolecular synthons proves to be a generally applicable strategy for 2D and quasi-2D halide perovskites, with potential extension to diverse organic cations. However, its merit extends to a broad range of organic-inorganic hybrid semiconductors. Particularly, the selection of functional groups and intermolecular interactions to be incorporated within the organic layer transcends far beyond CA dimers and H-bonding network. For instance, x effect (R-T, 1-p, or x-d interactions) between organic cations, electrostatic interactions, and even chirality, could also be readily implemented. Further explorations in this regard will introduce enhanced versatility in these hybrid materials as the next-generation semiconductors, where the collective benefits of conventional organic and inorganic counterparts readily converge.

In operation, bulk bromide perovskite single crystals were obtained through slow-cooling a solution composed of HBr, PbBr₂, and the organic ammonium salts. The iodide counterparts were obtained with PbI₂ and the organic ammonium salts in HI and H₃PO₂ as solvents. MABr or MAI were added to obtain n>1 structures. Additionally, dimethylformamide (DMF) was added to assist the formation of (BrCA3)₂MAPb₂Br₇ single crystals only. The detailed crystal growth parameters such as the ratio of solvents and the concentration of each precursor are specified in TABLE 1.

TABLE 1

| | Cation | PbBr₂ | MABr | HBr | Additive | |
|---|---|---|---|---|---|---|
| | (mg) | (mg) | (mg) | (μL) | (μL) | Purpose^{a} |
| (mCA1)₂ | 3.4 | 10.1 | | 250 | | SCₛₒₗᵥₑ |
| PbBr₄ | 5.4 | 11.1 | | 250 | | FG^{a} 50° C. |
| (TPA3)₂ | 0.4 | 20.2 | | 300 | | SC; FG 50° C. |
| PbBr₄ | 1.5 | 20.1 | | 500 | | SCₛₒₗᵥₑ |
| (BrCA3)₂ | 3.3 | 11.0 | | 700 | | SCₛₒₗᵥₑ |
| PbBr₄ | 1.0 | 11.0 | | 450 | | SC |
| | | | | | | FG 70° C. |
| | 5.1 | 10.8 | | 800 | | SC |
| | 3.3 | 17.1 | | 700 | | SC |
| (BrCA3)₂ | 1.1 | 20.5 | 17.7 | 300 | DMF 50 | FG 70° C. |
| MAPb₂Br₇ | 1.2 | 26.5 | 20.2 | 300 | DMF 50 | SCₛₒₗᵥₑ |
| n = 2^{b} | | | | | | |

| | Cation | PbI₂ | MAI | HI | H₃PO₂ | Additive | |
|---|---|---|---|---|---|---|---|
| | (mg) | (mg) | (mg) | (μL) | (μL) | (μL) | Purpose |
| (TPA3)₂ | 2.1 | 19.8 | | 1045 | 100 | | SC; FG 70° C. |
| PbI₄ | 0.8 | 20.0 | | 440 | 100 | | SCₛₒₗᵥₑ |
| (BrCA3)₂ | 1.9 | 19.7 | | 200 | 100 | | SCₛₒₗᵥₑ |
| PbI₄ | 1.0 | 25.4 | | 180 | 20 | | FG 70° C. |
| | 5.2 | 125.3 | | 540 | 60 | | FG 70° C. |
| | 2.5 | 60.0 | | 360 | 40 | | FG 70° C. |
| (BrCA3)₂ | 1.0 | 37.7 | 18.0 | 180 | 20 | | SC |
| (MAPbI₃)₁₋₂ | 1.0 | 37.4 | 22.4 | 180 | 20 | | SC |
| PbI₄ | 1.0 | 32.8 | 24.7 | 180 | 20 | | SC |
| n = 2-3^{c} | 1.5 | 33.1 | 24.9 | 180 | 20 | | SC |
| | 0.9 | 32.8 | 25.2 | 180 | 20 | Toluene 50 | SC |

| | Cation | SnI₂ | HI | H₃PO₂ | |
|---|---|---|---|---|---|
| | (mg) | (mg) | (μL) | (μL) | Purpose |
| (BrCA3)₂ | 1.0 | 20.0 | 200 | 25 | FC |
| SnI₄ | | | | | |

^{a}SC: slow cooling; SCₛₒₗᵥₑ: crystal quality suitable for solving the structure with SC-XRD; FG: floating growth; FC: fast-cooling.
^{b}DMF is necessary for growing (BrCA3)₂MAPb₂Br₇. Without DMF addition, slow-cooling resulted in either n = 1 or 3D perovskites as majority. Other additives (ethanol, isopropanol) were screened as well, but did not result in formation of n = 2 crystals.
^{c}Phase-pure n > 1 iodide crystals were extremely difficult to obtain. Listed here are a few precursor solutions used. Slow-cooling typically gave a cloudy suspension of crystals with mixed phases. Toluene was identified as a suitable additive to drive the formation of phase-pure n = 2 or n = 3 iodide crystals. Other additives were screened: methanol, ethanol, isopropanol were unsuitable for our system which drove liquid phase separation; acetonitrile and acetone did not lead to phase separation, but did not drive the formation of n = 2 or n = 3 iodide species; chlorobenzene and 1,2-dichlorobenzene could be used to replace toluene.

The precursors and solvents were mixed in a 2 mL scintillation vial. After being tightly capped, the sample vial was heated carefully with a heat gun over 100° C. to induce mild refluxing of the solvents until materials were completely dissolved and the solution was clear. This process was carried out with great cautions in a fume hood with sash closed. Sonication was occasionally used to assist the dissolution of materials but magnetic stirring was avoided. To avoid rapid precipitation upon placing the vial in a boiling water bath, the mixture was then stabilized on a 90° C. hotplate to ensure no precipitate was observed even with mild evaporation of solvents inside the vial and condensation on the wall thereafter. Then, the vial was transferred to and sealed in a Dewar flask containing boiling water, which was then stored at ambient conditions to allow slow-cooling for about 72 to about 96 hours until the water bath reached room temperature. The crystal was stored in solution until being removed for structure determination and face indexing.

### Perovskite Nanowire Growth

Nanowires of perovskite single crystals were grown with a variety of methods including floating growth and fast cooling. The preparation methods of precursor solution were similar to those mentioned above for perovskite single crystal growth. The exact composition of solution varied in each scenario and is documented in TABLE 1.

Floating growth was used for n=1 [PbBr₄]²⁻, n=1 [PbI₄]²⁻, and n=2 bromide nanowires. The method accelerates the crystal growth at air-liquid interface and has been well-documented. In detail, a clear and refluxing solution containing perovskite precursors was cooled to 70° C. and kept undisturbed until the temperature had stabilized, sometimes indicated by the formation and stabilization of precipitates. The exact temperature varies depending on the material composition, precursor concentration, etc. A few (1-5) μL of the supernatant were extracted with a 10 μL micropipette onto a glass substrate at ambient conditions in air. Nucleation and growth quickly initiated at the air-droplet interface. This process was be monitored under an optical microscope. Nanocrystals grown with this method were then picked-up by gently touching the droplet surface with various substrates including TEM grids, silicon (Si), Si/silica (SiO₂) for SEM, Si/SiO₂ or polydimethylsiloxane substrates (from GelPak, PF-30-X4) for optical characterizations. Leftover solvents were gently absorbed with a piece of filter paper.

Fast cooling was used to synthesize n=1 [SnI₄]²⁻. This method was same as slow cooling except that the cooling speed was accelerated to a few minutes. In detail, the clear and refluxing precursors solution was cooled to room temperature without external control and kept undisturbed until a precipitate formed. The precipitated crystals were then transferred to various substrates with similar methods as described before.

For n>1 lead-iodide nanowires, regular slow-cooling was used.

### Epitaxial Growth of Perovskite Nanowire Heterostructures

This method uses longitudinal epitaxial nanowire heterostructures with (BrCA3)₂PbI₄ core and (BrCA3)₂PbBr₄ shell as example. First, (BrCA3)₂PbI₄ nanowires were prepared on Si/SiO₂ or pdms substrates. (BrCA3)₂PbBr₄ shell was further grown with the floating growth method starting from a 70° C. droplet. The droplet was left cooled-down for a few seconds giving an oversaturated solution. A few particles might already crash out at the air-liquid interface. Then, the substrate having core nanowires was placed upside-down to cover the shell droplet leading to immediate epitaxial growth of shell materials on the as-grown core. The substrate was then removed from the droplet and leftover solvent was dried.

### Methods

### Materials

Lead bromide (PbBr₂, 99.999% trace metals basis, #398853), lead iodide (PbI₂, 99.999% trace metals basis, perovskite grade, #900168), tin iodide (SnI₂, AnhydroBeads™, −10 mesh, 99.99% trace metals basis, #409308), hydrobromic acid (HBr, 48 wt. % in H₂O), hydroiodic acid (HI, 57 wt. % in H₂O), hypophosphorous acid (H₃PO₂, 50 wt. % in H₂O) were purchased from Millipore Sigma. Methylammonium bromide (MABr, >99.99%, #SKU MS301000), Methylammonium iodide (MAI, >99.99%, #SKU MS101000) were purchased from Greatcell Solar Materials. Deuterated dimethyl sulfoxide (DMSO-d6) and deuterated chloroform (CDCl₃) were purchased from Millipore Sigma. Anhydrous solvents used in organic synthesis were purchased from Millipore Sigma. Precursors used are specified in following sections.

### Perovskite Single Crystal Growth for Crystal Structure Determination and Face Indexing

Bulk bromide perovskite single crystals were obtained through slow-cooling a solution composed of HBr, PbBr₂, and the organic ammonium salts. The iodide counterparts were obtained with PbI₂ and the organic ammonium salts in HI and H₃PO₂ as solvents. MABr or MAI were added to obtain n>1 structures. Additionally, dimethylformamide (DMF) was added to assist the formation of (BrCA3)₂MAPb₂Br₇ single crystals only. The detailed crystal growth parameters such as the ratio of solvents and the concentration of each precursor are specified in TABLE 1.

In detail, the precursors and solvents were mixed in a 2 mL scintillation vial. After being tightly capped, the sample vial was heated carefully with a heat gun over 100° C. to induce mild refluxing of the solvents until materials were completely dissolved and the solution was clear. This process was carried out with great cautions in a fume hood with sash closed. Sonication was occasionally used to assist the dissolution of materials but magnetic stirring was avoided. To avoid rapid precipitation upon placing the vial in a boiling water bath, the mixture was then stabilized on a 90° C. hotplate to ensure no precipitate was observed even with mild evaporation of solvents inside the vial and condensation on the wall thereafter. Then, the vial was transferred to and sealed in a Dewar flask containing boiling water, which was then stored at ambient conditions to allow slow-cooling for 72-96 hours until the water bath reached room temperature. The crystal was stored in solution until being removed for structure determination and face indexing.

### Perovskite Nanowire Growth

Nanowires of perovskite single crystals were grown with a variety of methods including floating growth and fast-cooling. The preparation methods of precursor solution were similar to those mentioned above for perovskite single crystal growth. The exact composition of solution varied in each scenario and is documented in TABLE 1.

Floating growth was used for n=1 [PbBr₄]²⁻, n=1 [PbI₄]²⁻, and n=2 bromide nanowires. The method accelerates the crystal growth at air-liquid interface and has been well-documented in D. Pan, et al. (2021). In detail, a clear and refluxing solution containing perovskite precursors was cooled to 70° C. and kept undisturbed until the temperature had stabilized, sometimes indicated by the formation and stabilization of precipitates. The exact temperature varies depending on the material composition, precursor concentration, etc. A few (1-5) μL of the supernatant were extracted with a 10 μL micropipette onto a glass substrate at ambient conditions in air. Nucleation and growth quickly initiated at the air-droplet interface. This process was be monitored under an optical microscope (FIG. 4). Nanocrystals grown with this method were then picked-up by gently touching the droplet surface with various substrates including TEM grids, silicon (Si), Si/silica (SiO₂) for SEM, Si/SiO₂ or polydimethylsiloxane substrates (from GelPak, PF-30-X4) for optical characterizations. Leftover solvents were gently absorbed with a piece of filter paper.

Fast-cooling was used to synthesize n=1 [SnI₄]²⁻. This method was same as slow-cooling except that the cooling speed was accelerated to a few minutes. In detail, the clear and refluxing precursors solution was cooled to room temperature without external control and kept undisturbed until a precipitate formed. The precipitated crystals were then transferred to various substrates with similar methods as described before.

For n>1 lead-iodide nanowires, regular slow-cooling was used.

### Epitaxial Growth of Perovskite Nanowire Heterostructures

This method uses longitudinal epitaxial nanowire heterostructures with (BrCA3)₂PbI₄ core and (BrCA3)₂PbBr₄ shell as example. First, (BrCA3)₂PbI₄ nanowires were prepared on Si/SiO₂ or pdms substrates. (BrCA3)₂PbBr₄ shell was further grown with the floating growth method starting from a 70° C. droplet. The droplet was left cooled-down for a few seconds giving an oversaturated solution. A few particles might already crash out at the air-liquid interface. Then, the substrate having core nanowires was placed upside-down to cover the shell droplet leading to immediate epitaxial growth of shell materials on the as-grown core. The substrate was then removed from the droplet and leftover solvent was dried.

### Single Crystal X-Ray Diffraction (SC-XRD)

Single crystals of the investigated compounds were coated with a trace of Fomblin oil and were transferred to the goniometer head of a Bruker Quest diffractometer. Data for (TPA3)₂PbI₄, (TPA3)₂PbBr₄ (296 K), (BrCA3)₂PbI₄, (BrCA3)₂PbBr₄ (300 K) and (BrCA3)₂PbBr₄ (150 K) were collected on an instrument with a fixed chi angle, a Mo Kα wavelength (λ=0.71073 Å) sealed tube fine focus X-ray tube, a single crystal curved graphite incident beam monochromator, and a Photon II area detector. Data for (BrCA3)₂ (MA) Pb₂Br₇, (TPA3)₂PbBr₄ (150 K) and (mCA1)₂PbBr₄ were collected on an instrument with kappa geometry, a Cu Kα wavelength (λ=1.54178 Å) I-μ-S microsource X-ray tube, a laterally graded multilayer (Goebel) mirror for monochromatization, and a Photon III C14 area detector. Both instruments were equipped with an Oxford Cryosystems low temperature device and examination and data collection were performed at 150 K, except for (TPA3)₂PbBr₄ and (BrCA3)₂PbBr₄, which were measured at both 150 K and 296 or 300 K, respectively. In particular, (BrCA3)₂PbBr₄ displayed a phase change between 150 and 300 K, and the crystal structure at 300 K was used for presentation materials.

Data were collected, reflections were indexed and processed, and the files scaled and corrected for absorption using APEX4 (Bruker (2022). Apex4, SAINT, Bruker AXS Inc.: Madison (WI), USA) and SADABS or TWINABS (L. Krause, R. Herbst-Irmer, G. M. Sheldrick & D. Stalke, J. Appl. Cryst. 48, 3-10 (2015)). The space groups were assigned using XPREP within the SHELXTL suite of programs (SHELXTL suite of programs, Version 6.14, 2000-2003, Bruker Advanced X-ray Solutions, Bruker AXS Inc., Madison, Wisconsin: USA, G. M. Sheldrick, A short history of SHELX. Acta Cryst. A64, 112-122 (2008)) and solved by dual methods using ShelXT (G. M. Sheldrick, SHELXT-Integrated space-group and crystal-structure determination. Acta Cryst. A71, 3-8 (2015)) and refined by full matrix least squares against F2 with all reflections using Shelxl2018 or Shelxl2019 (G. M. Sheldrick, Crystal structure refinement with SHELXL. Acta Cryst. C71, 3-8 (2015)) using the graphical interface Shelxle (C. B. Hübschle, G. M. Sheldrick & B. Dittrich, ShelXle: a Qt graphical user interface for SHELXL. J. Appl. Cryst. 44 (6), 1281-1284, (2011)).

Where not specified otherwise H atoms were handled as follows: H atoms attached to carbon and nitrogen atoms as well as hydroxyl hydrogens were positioned geometrically and constrained to ride on their parent atoms. C—H bond distances were constrained to 0.95 Å for aromatic and alkene C—H moieties, and to 0.99 and 0.98 Å for aliphatic CH₂ and CH₃ moieties, respectively. Methyl CH₃, ammonium NH₃⁺ and hydroxyl H atoms were allowed to rotate but not to tip to best fit the experimental electron density. Water H atom positions were refined and O—H distances were restrained to 0.84 (2) Å. Where necessary, water H ··· H distances were restrained to 1.36 (2) Å, and H atom positions were further restrained based on hydrogen bonding considerations. Uᵢₛₒ (H) values were set to a multiple of U_{eq} (C) with 1.5 for CH₃, NH₃⁺ and OH, and 1.2 for C—H and CH₂ units, respectively.

Complete crystallographic data, in CIF format, have been deposited with the Cambridge Crystallographic Data Centre (CCDC), with the deposition number 2292512-2292519. CCDC contains the supplementary crystallographic data for this paper. These data can be obtained free of charge from The Cambridge Crystallographic Data Centre via www.ccdc.cam.ac.uk/data_request/cif.

### Face Indexing of Single Crystals

A suitable well-shaped single crystal representative of the bulk of each sample was selected using Carl Zeiss Discovery. V8 crystal microscope and mounted with the help of a trace of Fomblin oil on a MiTeGen micromesh mount (80 μm diameter mesh area with 15 μm openings). The mounted crystal was transferred to the goniometer head of the molybdenum wavelength Bruker Quest diffractometer described above (the same as used for data collection) precooled to the specified temperature. Data for a unit cell determination were collected using APEX4 (three times 12 frames with 0.5° frame width). After determination of a preliminary unit cell, the crystal was rotated around phi (360° rotation) and an image was collected every one degree. Full data were then collected and the structure was determined to establish the standard unit cell, and this unit cell was then loaded by reimporting the result of the integration of all data. Then, using the Apex4 subroutine for face indexing, crystal faces with indices<3 for h, k and 1 along the viewing direction of each image were identified, and the distance to the center of rotation was measured until all visible crystal faces were accounted for and the shape of the crystal determined from crystal faces did match the actual shape of the crystal. Results were used for absorption correction (for samples not twinned by non-merohedry) and to establish the shape and habit of crystals.

### Steady State Optical Measurements

All bright-field images were collected with a custom Olympus BX53 microscope equipped with a polarizer. All PL images were taken using an X-Cite Series 120 Q lamp as the excitation source. A coherent continuous wave OBIS 375 nm laser excitation source was used for PL spectrum measurements and selected-area excitation in waveguide study. PL spectra were collected with a SpectraPro HRS-300 spectrometer.

### Optically Pumped Lasing Measurements

Nanowires on Si/SiO₂ substrates were optically pumped with a 400 nm femtosecond beam generated with a Ti: Sapphire seed laser and ultrafast amplifier (Spectra-Physics, Solstice Ace; 1 kHz, 100 fs, 800 nm, linear polarization) and second harmonic generation. An electronic shutter controlled the number of pulses per exposure, and a variable neutral-density optical attenuator was used to control the excitation power. The sample was mounted in a N₂-filled. Experiments were performed at 88 K. The cryostat was placed on an inverted microscope. Laser beam was defocused to cover the entire crystal under investigation. A 420 nm long pass dichroic mirror beam splitter was used to eliminate collection of excitation light. The spectra were collected using a grating spectrometer (50 μm slit width, 1200 g/mm blaze holographic grating, and liquid-nitrogen-cooled Si CCD array detector). The sample exposure time was varied between 200 ms and 2 s. The laser fluence was calculated based on the spot size measured under microscope and the average power determined using a calibrated power meter.

### Emission Polarization and Data Analysis

Instead of analyzing PL spectra, PL images were collected with an emission polarizer and analyzed with imageJ. In detail, a region of interest (ROI) unique to each nanowire to avoid analyzing the waveguided light at the edge which would complicate the results. The total ROI-specific intensity at each polarizer angle was calculated and used for data plots. Exposure time used to collect the PL images was same across one measurement set and was chosen carefully so that both the tip and body emission (i.e. emission near the excitation spot) were below saturation. Regarding the twisted nanowire in FIG. 14, Panel B, three ROIs were used to analyze the polarization at the top, middle, and the bottom of the crystal.

### Waveguide Loss Coefficient Measurement

Waveguide losses were assessed according to the propagation-distance-dependent relative tip emission intensity collected and analyzed with far-field PL images and imageJ. In detail, the 375 nm laser beam (ø: ca. 15 nm) was focused at various positions on each nanowire and the distances from the focal point to the tip were calculated as light propagation distances (D). Exposure time used to collect the PL images was same across one measurement set and was chosen carefully so that both the tip and body emission (i.e. emission near the excitation spot) were below saturation. ROI was used to analyze the total intensity of tip and body emission. Each PL image was separated into red, green, and blue channels. Green channels were used to represent the material inherent waveguide loss while blue channel was affected by self-absorption, and red channel had low signal/noise ratio. Relative tip emission (Iₜᵢₚ/I_{body}) was calculated and plotted against/). The data plot was fitted with the waveguide loss equation (Iₜᵢₚ/I_{body}=Ae^{-αD}) to obtain the loss coefficient.

### Morphology Characterizations

Scanning Electron Microscopy (SEM) was conducted with a Hitachi S-4800 Field Emission SEM. The Transmission Electron Microscopy (TEM) image and electron diffraction pattern were obtained on a 200 kV JEOL JEM-F200 field-emission microscope equipped with a CMOS camara (Gatan Rio16). Atomic Force Microscopy (AFM) was conducted with an Asylum Cypher ES AFM.

### NMR

NMR was acquired at room temperature with a Bruker Avance III HD 400 MHZ spectrometer equipped with a 2-channel Nanobay console and a 5 mm BBFO Z-gradient SmartProbe, or Bruker NEO 500 MHz equipped with prodigy liquid-nitrogen cooled cryoprobe with BBFO configuration. NMR spectra were analyzed with Mestrenova.

### Data Presentation and Visualization

The program Mercury (C. F. Macrae, et al., J. Appl. Cryst. 41, 466-470, (2008).) was used for crystal structure illustration in this article. Bright field, PL, and SEM images were analyzed in imageJ. Translations and rotations were executed when necessary. The Blender software was used for 3D modeling in FIG. 2A and FIG. 4B FIG. 7, Panel A and FIG. 14, Panel B.

### Synthesis of Organic Cations

### (mCA1-Br), 3-carboxyphenyl)methylammonium bromide

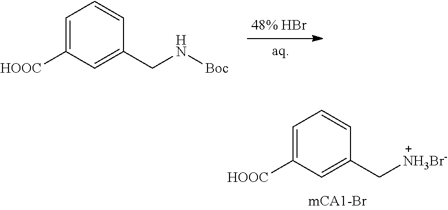

The boc-protected amine, 3-(((tert-butoxycarbonyl)amino)methyl)benzoic acid (from Ambeed, 1 mmol, 1 eq.) was added to a 4 mL vial. Then, 48% aqueous HBr solution (3 mL, excess) was added to cleave the boc protecting group and form the ammonium bromide in-situ. The mixture was stirred vigorously at 50° C. overnight, during which the heterogenous mixture gradually became a homogenous suspension. Water was added to obtain a clear solution, which was washed 3 times with dichloromethane. Then, the water phase was collected and concentrated. The product was recrystallized in water, filtered, and dried in vacuum at 60° C. to give a white solid. Yield: 47.0%. ¹H NMR (500 MHZ, DMSO-d6) δ 13.09 (s, 1H), 8.19 (s, 3H), 8.09 (s, 1H), 7.95 (d, J=7.8 Hz, 1H), 7.71 (d, J=7.8 Hz, 1H), 7.56 (t, J=7.7 Hz, 1H), 4.12 (s, 2H). 13C NMR (126 MHZ, DMSO-d6) δ 166.94, 134.43, 133.43, 131.11, 129.87, 129.32, 128.92, 41.91.

BrCA3, TPA3, FCA3, and MeCA3 were synthesized according to the following general scheme.

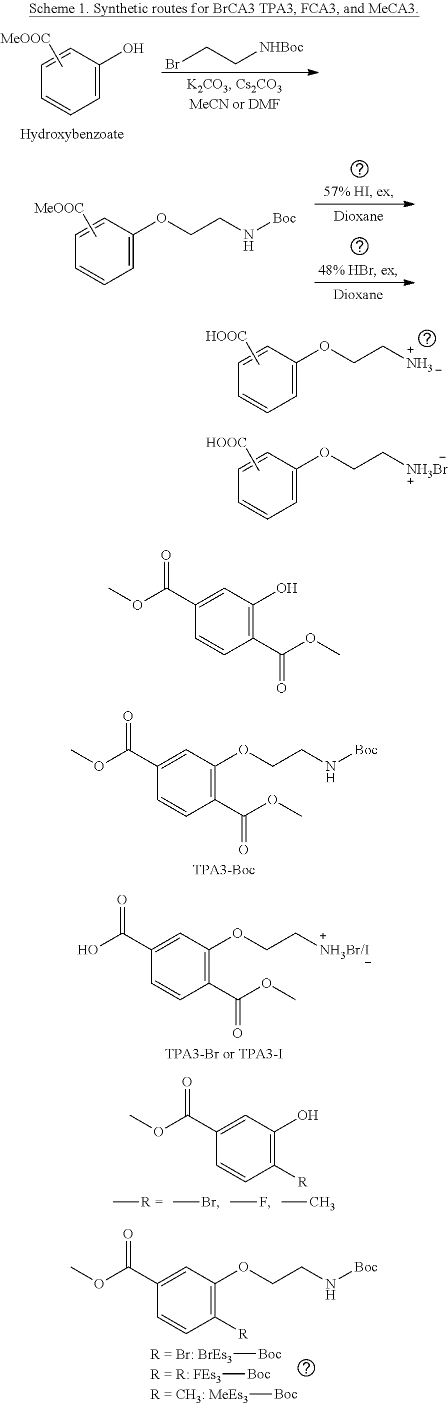

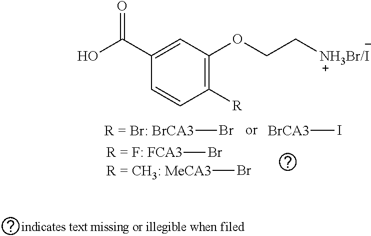

### First Step: Attaching Boc-Protected Amine Side Chain to Hydroxybenzoates

Hydroxybenzoates (1.0 eq.), potassium carbonate (K₂CO₃, from Millipore Sigma, 2.0 eq.), and tert-butyl (2-bromoethyl) carbamate (from Millipore Sigma, 1.5-2.0 eq.) were added to round-bottom flask charged with a stir bar. After a brief purge with Ar, anhydrous acetonitrile (MeCN, 0.1-0.2 M) was added. After extensive purging with Ar, the suspension was stirred at 90-95° C. to induce refluxing of MeCN for 12-24 h. The reaction can be further accelerated by addition of cesium carbonate (Cs₂CO₃, from Millipore Sigma, 0.5-1.0 eq.) or by replacing the solvent with anhydrous dimethylformamide (DMF) but without increasing the temperature.

Water was added, and the crude product was extracted with dichloromethane, dried over magnesium sulfate, filtered, and concentrated before been further purified with silica column chromatography (hexane/ethyl acetate). Product (boc-protected amine) and starting material (hydroxybenzoate) typically have similar R_{f} values and can be indistinguishable during column chromatography. Hence, considerable consumption of the starting material is crucial to obtain products with decent purity. However, a small amount of starting material in the final product can be further removed during the purification after converting the product to the ammonium salts.

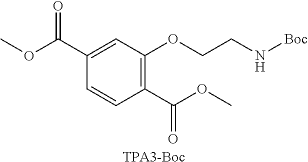

### (TPA3-Boc), dimethyl 2-(2-((tert-butoxycarbonyl)amino) ethoxy) terephthalate

Materials: dimethyl 2-hydroxyterephthalate (TPA-OH, 3.034 mmol, 1 eq.), K₂CO₃ (3.034 mmol, 1 eq.), Cs₂CO₃ (3.034 mmol, 1 eq.), tert-butyl (2-bromoethyl) carbamate (6.068 mmol, 2 eq.), anhydrous DMF (20 mL, 0.15 M). Near 100% starting material consumption. Final product: yellow gel. Yield 90.1%. ¹H NMR (400 MHZ, CDCl₃) δ 7.85 (d, J=8.0 Hz, 1H), 7.67 (dd, J=8.0, 1.4 Hz, 1H), 7.61 (d, J=1.3 Hz, 1H), 5.48 (s, 1H), 4.18 (t, J=5.0 Hz, 2H), 3.94 (s, 6H), 3.59 (q, J=5.2 Hz, 2H), 1.45 (s, 9H).

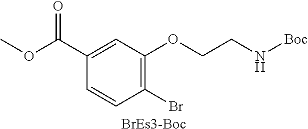 [SMILES: COC(=O)c1ccc(Br)c(OCCNC(=O)OC(C)(C)C)c1 ; "BrEs3-Boc"]

### (BrEs3-Boc), methyl 4-bromo-3-(2-((tert-butoxycarbonyl)amino) ethoxy)benzoate

Materials: methyl 4-bromo-3-hydroxybenzoate (4.328 mmol, 1 eq.), K₂CO₃ (8.656 mmol, 2 eq.), tert-butyl (2-bromoethyl) carbamate (6.492 mmol, 1.5 eq.), anhydrous MeCN (35 mL, 0.125 M). Hydroxybenzoate not fully consumed. Final product: pale yellow powder (ca. 6 mol % hydroxybenzoate). Yield 86.2%. ¹H NMR (400 MHZ, CDCl₃) δ 7.61 (d, J=8.6 Hz, 1H), 7.53 (dq, J=3.8, 1.8 Hz, 2H), 5.05 (s, 1H), 4.14 (t, J=5.0 Hz, 2H), 3.91 (s, 3H), 3.61 (q, J=5.4 Hz, 2H), 1.46 (s, 9H).

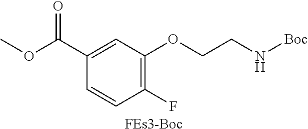 [SMILES: COC(=O)c1ccc(F)c(OCCNC(=O)OC(C)(C)C)c1 ; "FEs3-Boc"]

### (FEs3-Boc), methyl 3-(2-((tert-butoxycarbonyl)amino) ethoxy)-4-fluorobenzoate

Materials: methyl 4-fluoro-3-hydroxybenzoate (5.462 mmol, 1 eq.), K₂CO₃ (10.924 mmol, 2 eq.), Cs₂CO₃ (2.731 mmol, 0.5 eq.), tert-butyl (2-bromoethyl) carbamate (8.194 mmol, 1.5 eq.), anhydrous MeCN (55 mL, 0.125 M). Hydroxybenzoate fully consumed. Final product: white powder. Yield 85%, ¹H NMR (400 MHZ, CDCl₃) δ 7.72-7.57 (m, 2H), 7.12 (dd, J=10.6, 8.6 Hz, 1H), 5.02 (s, 1H), 4.14 (t, J=5.1 Hz, 2H), 3.91 (s, 3H), 3.58 (q, J=5.3 Hz, 2H), 1.45 (s, 9H).

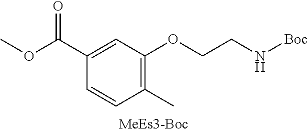 [SMILES: "MeEs3-Boc" ; COC(=O)c1ccc(C)c(OCCNC(=O)OC(C)(C)C)c1]

### (MeEs3-Boc), methyl 3-(2-((tert-butoxycarbonyl)amino) ethoxy)-4-methylbenzoate

Materials: methyl 3-hydroxy-4-methylbenzoate (8.728 mmol, 1 eq.), K₂CO₃ (17.656 mmol, 2 eq.), Cs₂CO₃ (4.364 mmol, 0.5 eq.), tert-butyl (2-bromoethyl) carbamate (13.092 mmol, 1.5 eq.), anhydrous MeCN (70 mL, 0.125 M). Hydroxybenzoate poorly consumed. Final product: white powder with 29 mol % hydroxybenzoates. Yield: 70%. ¹H NMR (500 MHz, CDCl₃) δ 7.58 (d, J=7.71, 1H), 7.45 (1H), 7.20 (d, J=7.75, 1H), 4.92 (s, 1H), 4.08 (t, J=5.1, 2H), 3.90 (s, 3H), 3.59 (q, J=4.6, 2H), 2.28 (s, 3H), 1.46 (s, 9H).

### Second Step: Simultaneous Amine Deprotection, Protonation, and Benzoate De-Esterification

To a round-bottom flask charged with a stir bar was added the boc-protected amine from the previous reaction (1 mmol, 1 eq.), followed by anhydrous dioxane (10 mL, 0.1 M). After complete dissolution, 48% HBr (aq. 10 mmol, 10 eq.) was added. After extensive Ar purging, the solution was heated at 95° C. to induce mild refluxing of solvents for 12 h. Similarly, 57% aqueous HI was used to synthesize iodide salts. The reaction mixtures will gradually turn yellow for the bromides and black for iodides.

Solvents were then completely removed from the solution through rotary evaporation, including water contained in HBr or HI. Then, the crude product was reprecipitated at least thrice by dissolution in acetone followed by addition of diethyl ether. The crude products usually have decent solubility in acetone for the iodine salts, but bromides are only poorly soluble. Thus, the crude bromide salts were extensively sonicated in acetone before addition of ether.

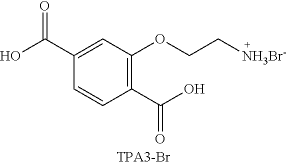

### (TPA3-Br), 2-(2,5-dicarboxyphenoxy)ethylammonium bromide

Materials: TPA3-Boc (1.128 mmol, 1 eq.), anhydrous dioxane (0.1 M), HBr (11.28 mmol, 10 eq.). Product reprecipitated with acetone/ether. The last reprecipitation was done with acetone/methanol/ether. Product: white powder. Yield: 67.4%. 1H NMR (500 MHZ, DMSO-d6) δ 13.25 (s, 2H), 7.91 (s, 3H), 7.79 (d, J=7.8 Hz, 1H), 7.69-7.62 (m, 2H), 4.32 (q, 2H), 3.26-3.21 (m, 2H). ¹³C NMR (126 MHz, DMSO-d6) δ 166.72, 166.35, 156.68, 134.93, 131.02, 126.24, 122.32, 115.77, 66.43, 38.43.

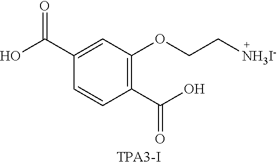

### (TPA3-I), 2-(2,5-dicarboxyphenoxy)ethylammomium iodide

Materials: TPA3-Boc (0.8556 mmol, 1 eq.), anhydrous dioxane (0.2 M), HI (8.5 mmol, 10 eq.). Product reprecipitated with acetone/ether. Product: pale yellow powder. Yield: 52.1%. ¹H NMR (500 MHZ, DMSO-d6) δ 13.28 (s, 2H), 7.86 (s, 3H), 7.79 (d, J=7.9 Hz, 1H), 7.68-7.62 (m, 2H), 4.32 (t, J=5.3 Hz, 2H), 3.24 (s, 2H). ¹³C NMR (126 MHz, DMSO-d6) δ 166.72, 166.35, 156.69, 134.94, 131.03, 126.25, 122.34, 115.85, 66.45, 38.45.

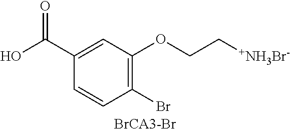

### (BrCA3-Br), 2-(2-bromo-5-carboxyphenoxy)ethylammonium bromide

Materials: BrEs3-Boc (0.8572 mmol, 1 eq.), anhydrous dioxane (0.1 M), HBr (8.57 mmol, 10 eq.). Product reprecipitated with acetone/ether. Product: white powder. Yield: 81.9%. ¹H NMR (500 MHz, DMSO-d6) δ 13.26 (s, 1H), 8.00 (s, 3H), 7.76 (d, J=8.2 Hz, 1H), 7.60 (d, J=1.8 Hz, 1H), 7.51 (dd, J=8.2, 1.8 Hz, 1H), 4.33 (t, J=5.3 Hz, 2H), 3.29-3.26 (m, 2H). ¹³C NMR (126 MHz, DMSO-d6) δ 166.46, 154.21, 133.49, 131.71, 123.69, 116.84, 114.49, 66.03, 38.15.

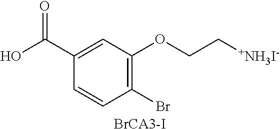

### (BrCA3-I), 2-(2-bromo-5-carboxyphenoxy)ethylammonium iodide

Materials: BrEs3-Boc (1.5549 mmol, 1 eq.), anhydrous dioxane (0.1 M), HI (15.5 mmol, 10 eq.). Product reprecipitated with acetone/ether. Last reprecipitation with acetone/methanol/ether. Product: white powder. Yield: 49.7%. ¹H NMR (500 MHZ, DMSO-d6) δ 13.27 (s, 1H), 7.93 (s, 3H), 7.76 (d, J=8.2 Hz, 1H), 7.61 (d, J=1.8 Hz, 1H), 7.52 (dd, J=8.2, 1.8 Hz, 1H), 4.32 (t, J=5.3 Hz, 2H), 3.29-3.25 (m, 2H). ¹³C NMR (126 MHz, DMSO-d6) δ 166.46, 154.20, 133.48, 131.71, 123.71, 116.84, 114.53, 66.09, 38.18.

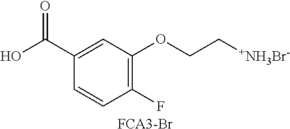

### (FCA3-Br), 2-(5-carboxy-2-fluorophenoxy)ethylammonium bromide

Materials: FEs3-Boc (3 mmol, 1 eq.), anhydrous dioxane (0.1 M), HBr (30 mmol, 10 eq.). Product reprecipitated with acetone/ether. Product: white powder. Yield: 67.0%. ¹H NMR (500 MHz, DMSO-d6) δ 13.14 (s, 1H), 7.96 (s, 3H), 7.70 (dd, J=8.2, 1.8 Hz, 1H), 7.63 (ddd, J=8.3, 4.4, 1.9 Hz, 1H), 7.39 (dd, J=11.0, 8.5 Hz, 1H), 4.32 (t, J=4.8 Hz, 2H), 3.27 (t, J=4.7 Hz, 2H). ¹³C NMR (126 MHz, DMSO-d6) δ 166.25, 154.66 (d, JCF=252.7 Hz), 145.58 (d, JCF=11.2 Hz), 127.71 (d, JCF=2.8 Hz), 123.75 (d, JCF=7.8 Hz), 116.43 (d, JCF=18.9 Hz), 116.22, 65.99, 38.23. ¹⁹F NMR (470 MHz, DMSO-d6, uncalibrated) δ −127.05.

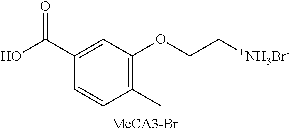

### (MeCA3-Br), 2-(5-carboxy-2-methylphenoxy)ethylammonium bromide

Materials: MeEs3-Boc (2 mmol, 1 eq.), anhydrous dioxane (0.1 M), HBr (20 mmol, 10 eq.). Product reprecipitated with acetone/ether. Last reprecipitation with acetone/methanol/ether. Product: white powder. Yield: 56.4%. ¹H NMR (500 MHz, DMSO-d6) δ 12.88 (s, 1H), 7.93 (s, 3H), 7.51 (d, J=7.7 Hz, 1H), 7.44 (s, 1H), 7.30 (d, J=7.7 Hz, 1H), 4.22 (t, J=4.2 Hz, 2H), 3.29-3.24 (m, 2H), 2.28 (s, 3H). ¹³C NMR (126 MHz, DMSO-d6) δ 167.64, 156.28, 132.50, 131.15, 130.20, 122.78, 112.11, 65.07, 38.94, 16.68.

Thus, while the disclosure has been illustrated and described in detail in the drawings and foregoing description, the same is to be considered as illustrative and not restrictive in character. It is understood that the embodiments have been shown and described in the foregoing specification in satisfaction of the best mode and enablement requirements. It is understood that one of ordinary skill in the art could readily make a nigh-infinite number of insubstantial changes and modifications to the above-described embodiments and that it would be impractical to attempt to describe all such embodiment variations in the present specification. Accordingly, it is understood that all changes and modifications that come within the spirit of the novel technology are desired to be protected.

What is claimed is:

1. An elongated single crystal layered halide perovskite nanowire with formula I
(A)₂PbX₄ (I)
wherein A is an organic ammonium salt selected from the group consisting of 2-(2,5-dicarboxyphenoxy) ethan-1-aminium (TPA3), 2-(2-bromo-5-carboxyphenoxy) ethan-1-aminium (BrCA3), 2-(5-carboxy-2-fluorophenoxy) ethan-1-aminium (FCA3), and 2-(5-carboxy-2-methylphenoxy) ethan-1-aminium (MeCA3); and X is Br or I.

2. The elongated single crystal layered halide perovskite nanowire of claim 1, wherein X is Br.

3. The elongated single crystal layered halide perovskite nanowire of claim 1, wherein X is I.

4. The elongated single crystal layered halide perovskite nanowire of claim 2, wherein A is TPA3.

5. The elongated single crystal layered halide perovskite nanowire of claim 2, wherein A is BrCA3.

6. The elongated single crystal layered halide perovskite nanowire of claim 2, wherein A is FCA3.

7. The elongated single crystal layered halide perovskite nanowire of claim 2, wherein A is MeCA3.

8. The elongated single crystal layered halide perovskite nanowire of claim 3, wherein A is TPA3.

9. The elongated single crystal layered halide perovskite nanowire of claim 3, wherein A is BrCA3.

10. The elongated single crystal layered halide perovskite nanowire of claim 1, comprising straight or bent nanowire of (BrCA3)₂PbBr₄, wherein the elongated single crystal layered halide perovskite nanowire has a maximum length up to 100 μm, a mean length of about 8.45 μm, and a mean diameter/width of about 400 μm.

11. A waveguide comprising the elongated single crystal layered halide perovskite nanowire of claim 10 with nanowire length of about 50 to about 100 μm and wherein the intrinsic light transport optical loss coefficient is about 2.7 dB/mm.

12. An elongated layered halide perovskite nanowire heterostructure comprising an elongated (BrCA3)₂PbI₄ core; and an elongated (BrCA3)₂PbBr₄ shell surrounding and encapsulating the elongated (BrCA3)₂PbI₄ core.

13. A method of making an elongated single crystal layered halide perovskite nanowire with formula II
(A)₂(CH₃NH₃⁺)ₙ₋₁MₙX₃ₙ₊₁ (II)
wherein A is an organic ammonium salt selected from the group consisting of 2-(2,5-dicarboxyphenoxy) ethan-1-aminium (TPA3), 2-(2-bromo-5-carboxyphenoxy) ethan-1-aminium (BrCA3), 2-(5-carboxy-2-fluorophenoxy) ethan-1-aminium (FCA3), and 2-(5-carboxy-2-methylphenoxy) ethan-1-aminium (MeCA3); M is a divalent metal cation, where the metal is Pb or Sn; X is Br or I, and n is 1, 2, or 3;
the method comprising the steps of:
a) preparing an aqueous working mixture of HX, MX₂, and A, with the proviso that when X is I, the working mixture also includes H₃PO₂;
b) optionally adding CH₃NH₃⁺X⁻ to the working mixture to yield an n>1 nanostructure;
c) optionally adding dimethylformamide (DMF) to the working mixture to obtain structures with n>1 and X=Br;
e) heating the working mixture of step d) to above 100° C. to induce mild refluxing of the working mixture to dissolve any undissolved components of the working solution to yield a clear working solution;
f) optionally applying sonication to the working solution of step e) to assist the dissolution;
g) holding the clear working solution at about 90° C. to ensure no precipitate formation;
h) fast-cooling the clear working solution from about 90° C. to 20° C. over a period of time, wherein the period of time is between 5 to 10 minutes to yield a plurality of elongated, single crystal layered halide perovskite nanowires with nano or micro-sized diameters;
i) optionally extracting a droplet of the clear working mixture at an adjustable temperature from about 40° C. to about 70° C. and rapidly cooling the droplet by placing it on a surface in room temperature air to yield a plurality of elongated, single crystal layered halide perovskite nanowires optionally grown at the droplet-air interface; and
j) optionally transferring the single crystal layered halide perovskite nanowires obtained in optional step i) onto the surface of a substrate selected from the group consisting of polydimethylsiloxane (PDMS), glass, quartz, and a silicon wafer.

14. The method of claim 13, wherein M is Pb.

15. The method of claim 13, wherein M is Sn.

16. The method of claim 14, wherein X is Br.

17. The method of claim 14, wherein X is I.

18. The method of claim 15, wherein X is I.

19. The method of claim 16, wherein A is TPA3.

20. The method of claim 16, wherein A is BrCA3.

21. The method of claim 16, wherein A is FCA3.

22. The method of claim 16, wherein A is MeCA3.

23. The method of claim 17, wherein A is TPA3.

24. The method of claim 17, wherein A is BrCA3.

25. The method of claim 18, wherein A is BrCA3.

26. A single crystal layered halide perovskite nanowire laser comprising nanowires of (BrCA3)₂SnI₄, prepared by the method of claim 25, wherein the single crystal layered halide perovskite nanowire laser has a light amplification threshold at 88 K is below 20 ρJ/cm².
